(19) United States
(12) Patent Application Publication
(10) Pub. No.: US 2025/0220890 A1
(43) Pub. Date: Jul. 3, 2025

(54) SEMICONDUCTOR DEVICE AND METHOD OF MANUFACTURING THE SAME

(71) Applicant: Samsung Electronics Co., Ltd., Suwon-si (KR)

(72) Inventors: HEEJAE CHAE, Suwon-si (KR); HUI-JUNG KIM, Suwon-si (KR); YONG KWAN KIM, Suwon-si (KR); KISEOK LEE, Suwon-si (KR); HYUNJIN LEE, Suwon-si (KR)

(21) Appl. No.: 18/786,931

(22) Filed: Jul. 29, 2024

(30) Foreign Application Priority Data
Dec. 29, 2023 (KR) 10-2023-0196720
Jan. 26, 2024 (KR) 10-2024-0012505

(51) Int. Cl. H10B 12/00

(52) U.S. Cl. CPC H10B 12/482; H10B 12/315; H10B 12/488

(57) ABSTRACT

A semiconductor device includes first and second active patterns adjacent to each other in a first direction, each of the first and second active patterns including first and second edge portions spaced apart from each other, a word line crossing between the first and second edge portions of each of the first and second active patterns and extending in a wave shape in the first direction, a bit line on the first edge portion of the first active pattern, and a storage node contact on the second edge portion of the first active pattern, wherein the first active pattern extends in a second direction intersecting the first direction, and the second active pattern extends in a third direction that is symmetrical to the second direction with respect to the first direction.

### CROSS-REFERENCE TO RELATED APPLICATIONS

This U.S. non-provisional patent application claims priority under 35 U.S.C. § 119 to Korean Patent Application No. 10-2023-0196720 filed on Dec. 29, 2023 and Korean Patent Application No. 10-2024-0012505 filed on Jan. 26, 2024, in the Korean Intellectual Property Office, the entire contents of each of which are hereby incorporated by reference.

### BACKGROUND OF THE INVENTION

The inventive concept relates to a semiconductor, and more particularly, relates to a semiconductor device and a method of manufacturing the same.

A semiconductor device may have relatively small sizes, multi-functional characteristics, and/or relatively low manufacture costs. The semiconductor device may be categorized as any one of semiconductor memory devices storing logical data, semiconductor logic devices processing logical data, and hybrid semiconductor devices having both the function of the semiconductor memory devices and the function of the semiconductor logic devices.

Due to increasing demand for high speed low-power electronic devices, semiconductor devices require a fast operating speed or a low operating voltage. To satisfy this demand, a semiconductor device needs a high integration density. Accordingly, much research is being conducted to improve the integration of semiconductor devices.

### SUMMARY

An object of the inventive concept is to provide to a semiconductor device that is easy to manufacture and has improved integration, and a method of manufacturing the same.

An object of the inventive concept is to provide to a semiconductor device with improved electrical characteristics and a method of manufacturing the same.

The problem to be solved by the inventive concept is not limited to the problems mentioned above, and other problems not mentioned will be clearly understood by those skilled in the art from the description below.

According to an aspect of the present disclosure, a semiconductor device includes a substrate provided with a first active pattern and a second active pattern, wherein the first active pattern and the second active pattern are adjacent to each other in a first direction, each of the first active pattern and the second active pattern includes a first edge portion, a second edge portion, a center portion therebetween, and the first direction is parallel to an upper surface of the substrate, a word line having a wave shape extending in the first direction and including a first portion overlapping the center portion of the first active pattern and a second portion overlapping the center portion of the second active pattern, a first bit line disposed on the first edge portion of the first active pattern, and a first storage node contact disposed on the second edge portion of the first active pattern. The first active pattern extends lengthwise in a second direction intersecting the first direction, and the second direction is parallel to the upper surface of the substrate. The second active pattern extends lengthwise in a third direction intersecting the first direction and the second direction, and the third direction is parallel to the upper surface of the substrate. The first active pattern and the second active pattern are symmetric in shape.

According to an aspect of the present disclosure, a semiconductor device includes a first active pattern and a second active pattern adjacent to each other in a first direction, each of the first and second active patterns including a first edge portion and a second edge portion spaced apart from each other, a word line crossing between the first and second edge portions of each of the first and second active patterns and extending in the first direction, a bit line on the first edge portion of the first active pattern, and a storage node contact on the second edge portion of the first active pattern. The first active pattern extends lengthwise in a second direction intersecting the first direction. The second active pattern extends lengthwise in a third direction intersecting the first direction and the third direction. The second direction and the third direction are symmetrical with respect to the first direction. The first direction, the second direction, and the third direction are on the same plane. Each of opposite sides of the word line has convex surfaces and concave surfaces alternately arranged in the first direction.

According to an aspect of the present disclosure, a semiconductor device includes a first active pattern and a second active pattern adjacent to each other in a first direction, each of the first active pattern and the second active pattern including a first edge portion and a second edge portion spaced apart from each other, a word line crossing between the first and second edge portions of each of the first and second active patterns and having a wave shape extending in the first direction, a bit line disposed on the first edge portion of the first active pattern, a storage node contact disposed on the second edge portion of the first active pattern, a landing pad disposed on the storage node contact, and a data storage pattern disposed on the landing pad. The first active pattern extends lengthwise in a second direction intersecting the first direction. The second active pattern extends lengthwise in a third direction intersecting the first direction and the second direction. The second direction and the third direction are symmetrical with respect to the first direction. The first direction, the second direction, and the third direction are on the same plane.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1A is a plan view showing a semiconductor device according to some embodiments of the inventive concept.

FIG. 1B is an enlarged view of a portion of the structure of FIG. 1A.

FIG. 1C is an enlarged view of a portion of the structure of FIG. 1A.

FIGS. 2A to 2D are cross-sectional views corresponding to lines A-A′, B-B′, C-C′, and D-D′ of FIG. 1A, respectively.

FIG. 3 is a plan view showing a semiconductor device according to some embodiments of the inventive concept.

FIGS. 4A and 4B are cross-sectional views corresponding to lines A-A′ and D-D′ of FIG. 1A, respectively.

FIG. 5 is a cross-sectional view corresponding to line C-C′ in FIG. 1A.

FIG. 6 is a plan view showing a semiconductor device according to some embodiments of the inventive concept.

FIGS. 7A to 7C are cross-sectional views corresponding to lines A-A′, C-C′, and D-D′ of FIG. 6, respectively.

FIG. 8 is a plan view showing a semiconductor device according to some embodiments of the inventive concept.

FIGS. 9A and 9B are cross-sectional views corresponding to lines B-B′ and D-D′ of FIG. 8, respectively.

FIG. 10 is a plan view showing a semiconductor device according to some embodiments of the inventive concept.

FIGS. 11A and 11B are cross-sectional views corresponding to lines A-A′ and D-D′ of FIG. 10, respectively.

FIGS. 12A and 12B are cross-sectional views corresponding to lines A-A′ and D-D′ of FIG. 10, respectively.

FIG. 13 is a plan view showing a semiconductor device according to some embodiments of the inventive concept.

FIGS. 14A to 14D are cross-sectional views corresponding to lines A-A′, B-B′, C-C′, and D-D′ of FIG. 13, respectively.

FIGS. 15, 16A, 16B, 17, 18A to 18D, 19, and 20A to 20D are views showing a method of manufacturing a semiconductor device according to some embodiments of the inventive concept.

FIGS. 21, 22A to 22C, 23, and 24A to 24C are views showing a method of manufacturing a semiconductor device according to some embodiments of the inventive concept.

FIGS. 25, 26A, and 26B are views showing a method of manufacturing a semiconductor device according to some embodiments of the inventive concept.

FIGS. 27, 28A and 28B are views showing a method of manufacturing a semiconductor device according to some embodiments of the inventive concept.

FIGS. 29, 30A and 30B are views showing a method of manufacturing a semiconductor device according to some embodiments of the inventive concept.

FIGS. 31A and 31B are views showing a method of manufacturing a semiconductor device according to some embodiments of the inventive concept.

### DETAILED DESCRIPTION

Hereinafter, in order to explain the inventive concept in more detail, embodiments according to the inventive concept will be described in more detail with reference to the accompanying drawings.

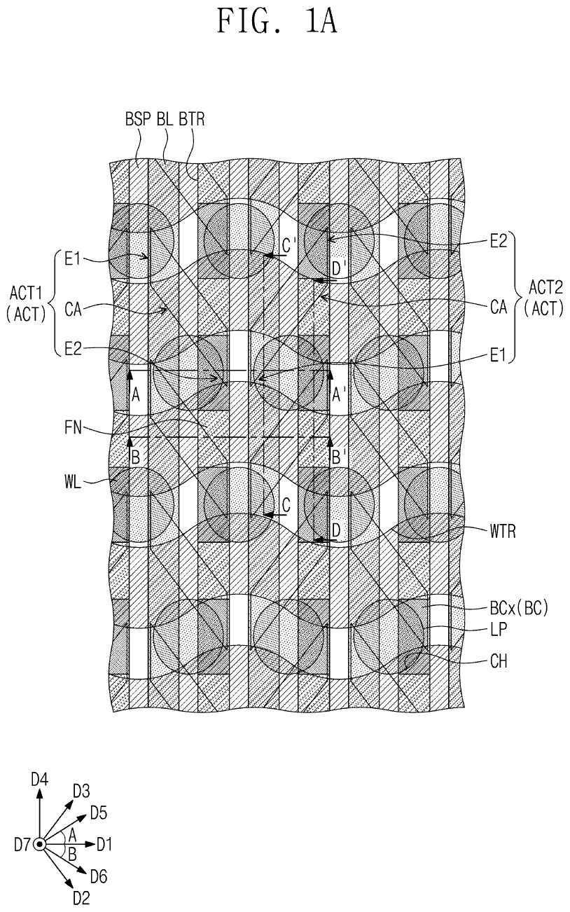

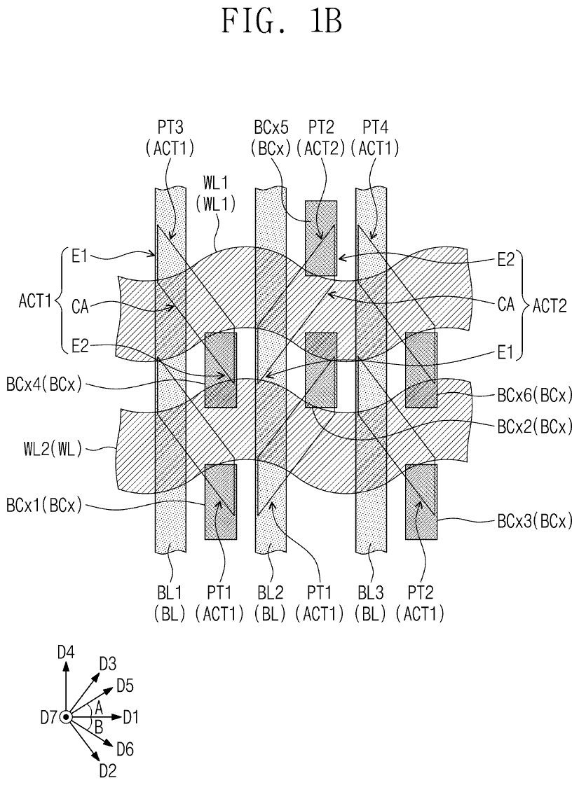

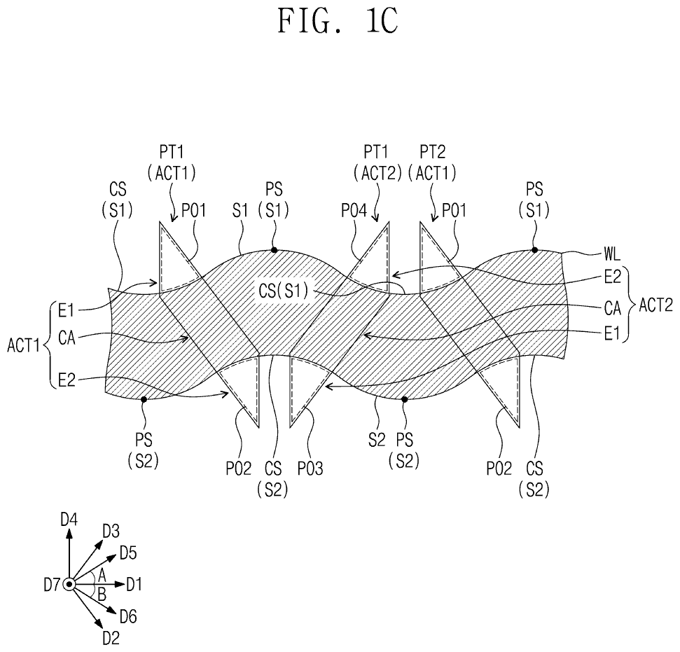

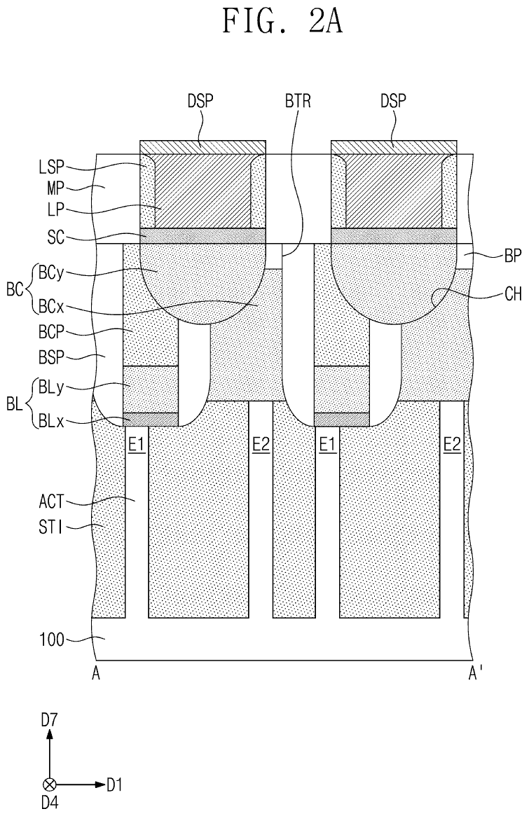

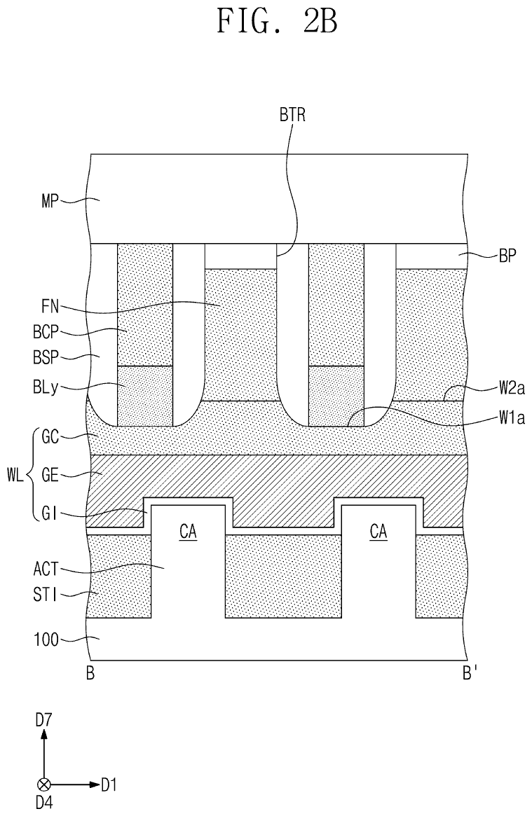

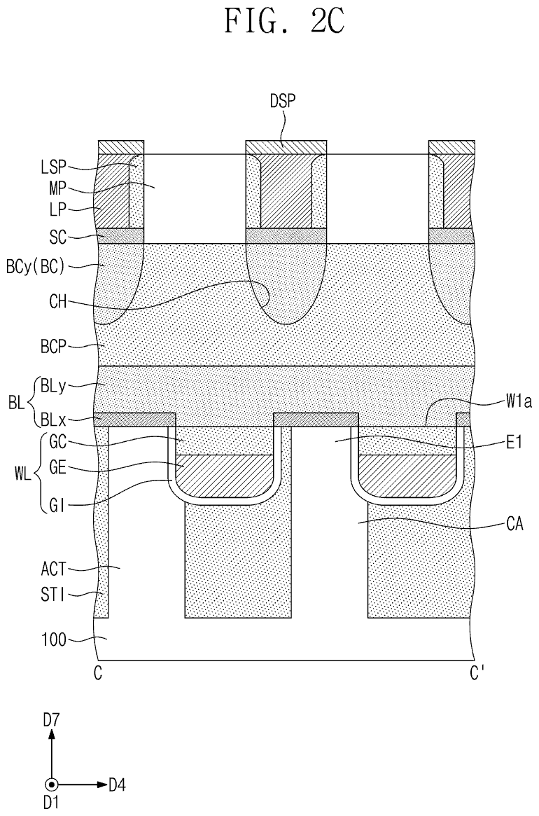

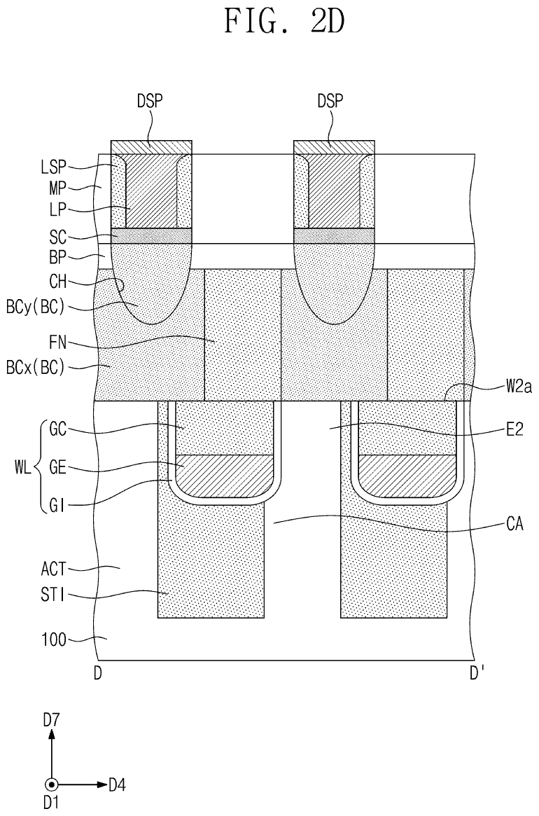

FIG. 1A is a plan view showing a semiconductor device according to some embodiments of the inventive concept. FIG. 1B is an enlarged view of a portion of the structure of FIG. 1A. FIG. 1C is an enlarged view of a portion of the structure of FIG. 1A. FIGS. 2A to 2D are cross-sectional views corresponding to lines A-A′, B-B′, C-C′, and D-D′ of FIG. 1A, respectively.

Referring to FIGS. 1A to 1C and 2A to 2D, a substrate 100 may be provided. The substrate 100 may be a semiconductor substrate, for example, a silicon substrate, a germanium substrate, or a silicon-germanium substrate.

A device isolation pattern STI may be disposed in the substrate 100 and an active pattern ACT may be defined. A plurality of active patterns ACT may be provided. As an example, the active patterns ACT may include a portion of the substrate 100 surrounded by the device isolation pattern STI. For convenience of explanation, unless otherwise specified, in this specification, the substrate 100 is defined to refer to a portion of the substrate 100 other than the above portion. The device isolation pattern STI may include or may be formed of an insulating material, for example, at least one of silicon oxide (SiO₂) and silicon nitride (SiN). The device isolation pattern STI may be a single layer formed of a single material or a composite layer containing two or more materials. As used herein, each of such phrases as “A or B”, “at least one of A and B”, “at least one of A or B”, “A, B, or C”, “at least one of A, B, and C”, and “at least one of A, B, or C” may include all possible combinations of the items enumerated together in a corresponding one of the phrases.

The active pattern ACT may include a first active pattern ACT1 and a second active pattern ACT2 adjacent to each other in a first direction D1 parallel to a lower surface of the substrate 100. The first active pattern ACT1 may have an elongated shape extending in a second direction D2 parallel to the lower surface of the substrate 100. For example, the first active pattern ACT1 may extend lengthwise in the second direction. The second active pattern ACT2 may have an elongated shape extending in a third direction D3 parallel to the lower surface of the substrate 100. For example, the second active pattern ACT2 may extend lengthwise in the third direction D3. The first to third directions D1, D2, and D3 may intersect each other. For example, the second direction D2 may intersect the first direction D1 in a clockwise direction at an angle greater than 0° and less than 60°. For example, the third direction D3 may intersect the first direction D1 in a counterclockwise direction at an angle greater than 0° and less than 60°. For example, the third direction D3 is symmetrical to the second direction D2 with respect to the first direction D1 or a fourth direction D4. The fourth direction D4 may be parallel to the lower surface of the substrate 100 and intersect the first to third directions D1, D2, and D3. For example, the first active pattern ACT1 and the second active pattern ACT2 have a symmetrical profile (is symmetric in shape), when viewed in a plan view. For example, the first active pattern ACT1 and the second active pattern ACT2, when viewed in a plan view, may be spaced increasingly farther apart in the first direction D1 along an imaginary line between therebetween. The imaginary line may extend in the fourth direction D4 which is parallel to the upper surface of the substrate 100 and perpendicular to the first direction D1. In some embodiment, a distance, in the first direction, between the imaginary line and the first active pattern ACT1 may be equal to a distance, in the first direction, between the imaginary line and the second active pattern ACT2.

Each of the first and second active patterns ACT1 and ACT2 may protrude in a direction perpendicular to the lower surface of the substrate 100 (e.g., a seventh direction D7 to be described later). As an example, the first and second active patterns ACT1 and ACT2 may include silicon (e.g., single crystal silicon). In some embodiments, the first and second active patterns ACT1 and ACT2 may be provided with the substrate 100. The first and second active patterns ACT1 and ACT2 may be epitaxially formed from the substrate 100, or may be formed by patterning the substrate 100 by etching.

The first active pattern ACT1 may include a plurality of first active patterns ACT1 arranged in the first direction D1 and the fourth direction D4 parallel to the lower surface of the substrate 100. For example, the first active pattern ACT1 may be repeatedly positioned in the first and fourth directions D1 and D4 to form the plurality of first active patterns ACT1. The fourth direction D4 may be parallel to the lower surface of the substrate 100 and intersect the first to third directions D1, D2, and D3. The fourth direction D4 may be perpendicular to the first direction D1. The second active pattern ACT2 may include a plurality of second active patterns ACT2 arranged in the first direction D1 and the fourth direction D4. The first active patterns ACT1 and ACT2 may be alternately arranged in the first direction D1.

The first active pattern ACT1 may include a first edge portion E1 and a second edge portion E2 spaced apart from each other in the second direction D2, and a center portion CA therebetween. The first edge portion E1 and the second edge portion E2 may be opposite end portions of the first active pattern ACT1 in the second direction D2. The first edge portion E1 and the second edge portion E2 of the first active pattern ACT1 may be arranged in order in the second direction D2.

The second active pattern ACT2 may include a first edge portion E1 and a second edge portion E2 spaced apart from each other in the third direction D3, and a center portion CA therebetween. The first edge portion E1 and the second edge portion E2 may be opposite end portions of the second active pattern ACT2 in the third direction D3. The first edge portion E1 and the second edge portion E2 of the second active pattern ACT2 may be arranged in order in the third direction D3.

The first edge portion E1 of the first active pattern ACT1 may be adjacent to the second edge portion E2 of the second active pattern ACT2 in the first direction D1. For example, the first edge portion E1 of the first active pattern ACT1 and the second edge portion E2 of the second active pattern ACT2 may be spaced apart from each other at a first distance in the first direction D1. The second edge portion E2 of the first active pattern ACT1 may be adjacent to the first edge portion E1 of the second active pattern ACT2 in the first direction D1. For example, the second edge portion E2 of the first active pattern ACT1 and the first edge portion E1 of the second active pattern ACT2 may be spaced apart from each other at a second distance in the first direction D1. The second distance may be different from the first distance. In some embodiment, the first distance may be greater than the second distance. The center portion of the first active pattern ACT1 may be adjacent to the center portion of the second active pattern ACT2 in the first direction. For example, the center portion of the first active pattern ACT1 and the center portion of the second active pattern ACT2 may be spaced apart from each other at a third distance in the first direction. In some embodiments, the third distance may be different from the first distance and the second distance. For example, the third distance may be a value between the second distance and the first distance.

The center portion CA of each of the first and second active patterns ACT1 and ACT2 may be provided below a word line WL, which will be described later. The word line WL may vertically overlap the center portion CA of each of the first and second active patterns ACT1 and ACT2. The center portions CA of the first and second active patterns ACT1 and ACT2 may be arranged to be spaced apart in the first direction D1.

Each of the first and second edge portions E1 and E2 and the center portion CA of the first and second active patterns ACT1 and ACT2 may include a doped impurity region having impurities (e.g., n-type or p-type impurities) therein. The impurity region may form a source drain region and/or a channel region of a transistor.

The first active patterns ACT1 adjacent to each other may be arranged side by side in the first direction D1 (or an opposite direction thereof) or the fourth direction D4 (or an opposite direction thereof). In this specification, the neighboring first active patterns ACT1 being arranged side by side in a certain direction, means that the first edge portions E1 of the first active patterns ACT1 adjacent to each other are arranged in the certain direction.

The neighboring second active patterns ACT2 may be arranged side by side in the first direction D1 (or the opposite direction thereof) or the fourth direction D4 (or the opposite direction thereof). In this specification, the neighboring second active patterns ACT2 being arranged side by side in a certain direction means that the first edge portions E1 of the neighboring second active patterns ACT2 are arranged in the certain direction.

The first active pattern ACT1 and the second active pattern ACT2 adjacent to each other may be arranged side by side in the first direction D1 (or the opposite direction thereof). In the present specification, the adjacent first active patterns ACT1 and the second active patterns ACT2 being arranged side by side in a certain direction means that the first edge portion E1 of the first active pattern ACT1 and the second edge portion E2 of the second active pattern ACT2 are arranged in the certain direction.

Referring to FIG. 1B, a first pattern PT1, a second pattern PT2, a fourth pattern PT4, and a third pattern PT3 of the first active pattern ACT1 may be arranged in a counterclockwise direction. The first pattern PT1 of the second active pattern ACT2 may be interposed between the first pattern PT1 and the second pattern PT2 of the first active pattern ACT1. The second pattern PT2 of the second active pattern ACT2 may be interposed between the third pattern PT3 and the fourth pattern PT4 of the first active pattern ACT1.

The first pattern PT1 of the first active pattern ACT1 and the first pattern PT1 of the second active pattern ACT2 immediately adjacent thereto may be arranged side by side in the first direction D1. The first pattern PT1 of the second active pattern ACT2 and the second pattern PT2 of the immediately adjacent first active pattern ACT1 may be arranged side by side in the first direction D1. The third pattern PT3 of the first active pattern ACT1 and the second pattern PT2 of the second active pattern ACT2 immediately adjacent thereto may be arranged in parallel in the first direction D1. The second pattern PT2 of the second active pattern ACT2 and the fourth pattern PT4 of the first active pattern ACT1 immediately adjacent thereto may be arranged in parallel in the first direction D1.

The first pattern PT1 of the first active pattern ACT1 and the third pattern PT3 of the immediately adjacent first active pattern ACT1 may be arranged side by side in the fourth direction D4. The second pattern PT2 of the first active pattern ACT1 and the fourth pattern PT4 of the immediately adjacent first active pattern ACT1 may be arranged in parallel in the fourth direction D4. The first pattern PT1 of the second active pattern ACT2 and the second pattern PT2 of the second active pattern ACT2 immediately adjacent thereto may be arranged in parallel in the fourth direction D4.

The first edge portion E1 of the first pattern PT1 of the first active pattern ACT1, the second edge portion E2 of the first pattern PT1 of the second active pattern ACT2, and the edge portion E1 of the second pattern PT2 of the first active pattern ACT1 may be arranged in order in the first direction D1. The first edge portion E1 of the third pattern PT3 of the first active pattern ACT1, the second edge portion E2 of the second pattern PT2 of the second active pattern ACT2, and the first edge portion E1 of the fourth pattern PT4 of the first active pattern ACT1 may be arranged in order in the first direction D1.

The first edge portion E1 of the first pattern PT1 of the first active pattern ACT1 and the first edge portion E1 of the third pattern PT3 of the first active pattern ACT1 may be arranged in order in the fourth direction D4. The first edge portion E1 of the second pattern PT2 of the first active pattern ACT1 and the first edge portion E1 of the fourth pattern PT4 of the first active pattern ACT1 may be arranged in order in the fourth direction D4. The first edge portion E1 of the first pattern PT1 of the second active pattern ACT2 and the first edge portion E1 of the second pattern PT2 of the second active pattern ACT2 may be arranged in order in the fourth direction D4.

According to the inventive concept, the first and second active patterns ACT1 and ACT2 may be arranged side by side in the first direction D1 (or the opposite direction thereof) or the fourth direction D4 (or the opposite direction thereof), thereby simplifying an arrangement of components in the semiconductor device. Accordingly, difficulty of patterning for forming a semiconductor device may be reduced, and as a result, manufacturing of the semiconductor device may be facilitated. Additionally, by arranging the components relatively simply, integration of the semiconductor device may be improved.

Referring to FIGS. 1A to 1C and 2A to 2D, the word line WL may cross the active patterns ACT and the device isolation pattern STI. The word line WL may be provided on the center portion CA of the first and second active patterns ACT1 and ACT2 and may be interposed between the first edge portion E1 and the second edge portion E2 of the first and second active patterns ACT1 and ACT2. The word line WL may be positioned repeatedly in the fourth direction D4 to form a plurality of word lines WL. Each of the word lines WL may extend in the first direction D1 and be spaced apart from each other in the fourth direction D4. As an example, one word line WL is formed on the center portion CA of each of the first active patterns ACT1 and the second active patterns ACT2 arranged side by side in the first direction D1 may extend in the first direction D1. For example, each active pattern of the first and second active patterns ACT1 and ACT2 may overlap a single word line.

Each of the word lines WL may include a gate electrode GE, a gate dielectric pattern GI, and a gate capping pattern GC. The gate electrode GE may penetrate the first and second active patterns ACT1 and ACT2 and the device isolation pattern STI in the first direction D1. The gate dielectric pattern GI may be interposed between the gate electrode GE and each of the first and second active patterns ACT1 and ACT2, and between the gate electrode GE and the device isolation pattern STI. The gate capping pattern GC may cover an upper surface of the gate electrode GE. As an example, the gate electrode GE may include or may be formed of a conductive material. For example, the gate electrode GE may be a single layer formed of a single material or a composite layer containing two or more materials. As an example, the gate dielectric pattern GI may include or may be formed of at least one of silicon oxide (SiO₂) and a high-k dielectric material. In this specification, the high-k dielectric material is defined as an insulating material that has a higher dielectric constant than silicon oxide. As an example, the gate capping pattern GC may include or may be formed of silicon nitride (SiN).

The word line WL may have a first upper surface W1a and a second upper surface W2a. The first upper surface W1a of the word line WL may be a portion of an upper surface of the word line WL located below a bit line BL, which will be described later, and the second upper surface W2a may be another portion of the upper surface of the word line WL. For example, the second upper surface W2a of the word line WL may be disposed below a fence pattern FN, which will be described later. For example, the first upper surface W1a of the word line WL may be positioned at a lower level than the second upper surface W2a.

Referring to FIG. 1C, the word line WL may extend in a fifth direction D5 parallel to the lower surface of the substrate 100 between the first and second edge portions E1 and E2 of the first pattern PT1 of the first active pattern ACT1. The fifth direction D5 may be a direction between the first direction D1 and the fourth direction D4. The fifth direction D5 may form a first angle A with the first direction D1 in a counterclockwise direction. The first angle A may be greater than 0° and less than 90°. As an example, the first angle A may be greater than 0° and less than or equal to 60°.

The word line WL may extend in a sixth direction D6 parallel to the lower surface of the substrate 100 between the first and second edge portions E1 and E2 of the first pattern PT1 of the second active pattern ACT2. The sixth direction D6 may be a direction opposite to the first direction D1 and the fourth direction D4. The sixth direction D6 may form second angle B with the first direction D1 in a clockwise direction. The second angle B may be greater than 0° and less than 90°. As an example, the second angle B may be greater than 0° and less than or equal to 60°.

Again, the word line WL may extend in the fifth direction D5 between the first and second edge portions E1 and E2 of the second pattern PT2 of the first active pattern ACT1.

In summary, the word line WL may extend in the fifth direction D5 on the center portion CA of each of the first active patterns ACT1 arranged in the first direction D1. Additionally, the word line WL may extend in the sixth direction D6 on the center portion CA of each of the second active patterns ACT2 arranged in the first direction D1.

As the first active patterns ACT1 and the second active patterns ACT2 are alternately arranged in the first direction D1, regions of the word line WL extending in the fifth direction D5 and regions of the word line WL extending in the sixth direction D6 may be alternately arranged in the first direction D1. Accordingly, the word line WL has a wave shape overlapping portions (e.g., the center portions CA) between the first and second edge portions E1 and E2 of the first and second active patterns ACT1 and ACT2. In some embodiments, the wave shape of the word line WL may have a substantially constant width in the fourth direction. In some embodiments, the word line WL may include a first portion overlapping the center portion of the first active pattern and a second portion overlapping the center portion of the second active pattern.

The word line WL may have opposite sides with a wave shape extending in the first direction D1. Among the two sides of the word line WL, a side facing the fourth direction D4 is defined as a first side S1, and the side facing the first side S1 is defined as a second side S2. For example, the first side S1 may be adjacent to the first edge portion E1 of the first active pattern ACT1 and the second portion E2 of the second active pattern ACT2, and the second side S2 may be adjacent to the second edge portion E2 of the first active pattern ACT1 and the first portion E1 of the second active pattern ACT2.

As each of the first and second side surfaces S1 and S2 extends in a wave shape, each of the first and second side surfaces S1 and S2 may have convex surfaces PS and concave surfaces CS alternately arranged in the first direction D1.

The convex surfaces PS of the first side S1 and the convex surfaces PS of the second side S2 may be convex in different directions. That is, the convex surfaces PS of the first side S1 may be convex toward the fourth direction D4, and the convex surfaces PS of the second side S2 may be convex toward the opposite direction of the fourth direction D4. A first portion of the word line WL with the convex surface PS of the first side S1 may refer to as a rising portion in the fourth direction D4, and a second portion of the word line WL with the concave surface CS of the first side S1 may refer to as a receding portion in the opposite direction of the fourth direction D4.

The concave surfaces CS of the first side S1 and the concave surfaces CS of the second side S2 may be concave in different directions. That is, the concave surfaces CS of the first side S1 may be concave toward a direction opposite to the fourth direction D4, and the concave surfaces CS of the second side S2 may be concave toward the fourth direction D4.

Each of the convex surfaces PS of the first side S1 may be adjacent to a corresponding one of the concave surfaces CS of the second side S2 in the fourth direction D4. Each of the concave surfaces CS of the first side S1 may be adjacent to a corresponding one of the convex surfaces PS of the second side S2 in the fourth direction D4. Each of the convex surfaces PS of the first side S1 may be adjacent to a corresponding one of the convex surfaces PS of the adjacent second side S2 in the second direction D2 or the third direction D3. The convex surfaces PS of the first side S1 and the convex surfaces PS of the second side S2 may be alternately arranged in a zigzag manner in the first direction D1. Each of the concave surfaces CS of the first side S1 may be adjacent to the concave surface CS of the adjacent second side S2 in the second direction D2 or the third direction D3. The concave surfaces CS of the first side S1 and the concave surfaces CS of the second side S2 may be alternately arranged in a zigzag manner in the first direction D1.

The first edge portion E1 of the first active pattern ACT1 and the second edge portion E2 of the second active pattern ACT2 may be provided on two adjacent concave surfaces CS of the first side S1 of the word line WL, respectively. The second edge portion E2 of the first active pattern ACT1 and the first edge portion E1 of the second active pattern ACT2 may be provided on two adjacent concave surfaces CS of the second side S2 of the word line WL, respectively.

According to the inventive concept, the word line WL may have a wave shape extending in the first direction D1 between the first and second edge portions E1 and E2 of each of the first and second active patterns ACT1 and ACT2. A portion of the word line WL adjacent to each of the first edge portion E1 of the first active pattern ACT1 and the second edge portion E2 of the second active pattern ACT2 may be concave toward an opposite direction to the fourth direction D4. In addition, another portion of the word line WL adjacent to each of the second edge portion E2 of the first active pattern ACT1 and the first edge portion E1 of the second active pattern ACT2 may be concave toward the opposite direction to the fourth direction D4. Accordingly, the area POI in contact with the first edge portion E1 of the first active pattern ACT1 and the bit line BL, which will be described later, and the area in contact with the second edge portion E2 of the first active pattern ACT1 and a lower storage node contact BCx, which will be described later, may increase. In addition, the area PO3 in contact with the first edge portion E1 of the second active pattern ACT2 and the bit line BL, which will be described later, and the area PO4 in contact with the second edge portion E2 of the second active pattern ACT2 and the lower storage node contact BCx, which will be described later, may increase. As a result, contacting components may be easily electrically connected, thereby improving electrical characteristics of the semiconductor device.

Referring to FIGS. 1A to 1C and 2A to 2D, the lower storage node contacts BCx may be provided on the second edge portions E2 of the first and second active patterns ACT1 and ACT2. The lower storage node contacts BCx may be in contact with the second edge portions E2 of the first and second active patterns ACT1 and ACT2. As an example, the lower storage node contact BCx may include at least one silicon (e.g., polysilicon containing impurities) and a metal material (e.g., Ti, Mo, W, Cu, Al, Ta, Ru, Ir, Co, etc.).

The lower storage node contacts BCx may be spaced apart from each other in the first and fourth directions D1 and D4. The lower storage node contacts BCx adjacent to each other in the first direction D1 may be spaced apart from each other with a bit line BL therebetween, which will be described later, interposed therebetween. The lower storage node contacts BCx adjacent to each other in the fourth direction D4 may be spaced apart from each other with the fence pattern FN therebetween, which will be described later, interposed therebetween.

Referring to FIG. 1B, a first lower storage node contact BCx1 may be provided on the second edge portion E2 of the first pattern PT1 of the first active pattern ACT1. A second lower storage node contact BCx2 may be provided on the second edge portion E2 of the first pattern PT1 of the second active pattern ACT2. A third lower storage node contact BCx3 may be provided on the second edge portion E2 of the second pattern PT2 of the first active pattern ACT1. A fourth lower storage node contact BCx4 may be provided on the second edge portion E2 of the third pattern PT3 of the first active pattern ACT1. A fifth lower storage node contact BCx5 may be provided on the second edge portion E2 of the second pattern PT2 of the second active pattern ACT2. A sixth lower storage node contact BCx6 may be provided on the second edge portion E2 of the fourth pattern PT4 of the first active pattern ACT1.

Again, referring to FIGS. 1A to 1C and 2A to 2D, the fence pattern FN may be provided on the word line WL. In detail, the fence pattern FN may be interposed between bit lines BL, which will be described later, adjacent to each other in the first direction D1, and between lower storage node contacts BCx adjacent to each other in the fourth direction D4. A lower surface of the fence pattern FN may be positioned at a higher level than the lower surface of the bit line BL.

A plurality of fence patterns FN may be provided. The plurality of fence patterns FN may be spaced apart from each other in the first and fourth directions D1 and D4. As an example, the fence pattern FN may include or may be formed of at least one of silicon oxide (SiO₂), silicon nitride (SiN), silicon oxycarbide (SiOC), and silicon oxycarbonitride (SiOCN).

A buffer pattern BP may cover an upper surface of the lower storage node contact BCx and an upper surface of the fence pattern FN. The buffer pattern BP may be interposed between bit lines BL, which will be described later, adjacent to each other in the first direction D1. As an example, the buffer pattern BP may include or may be formed of at least one of silicon oxide, silicon nitride, and silicon oxynitride. The buffer pattern BP may be a single layer formed of a single material or a composite layer containing two or more materials.

A bit line trench region BTR may be defined between neighboring lower storage node contacts BCx in the first direction D1 and between the fence patterns FN. The bit line trench region BTR may extend in the fourth direction D4 on the first edge portion E1 of the first and second active patterns ACT1 and ACT2. An upper portion of the first edge portion E1 of the first and second active patterns ACT1 and ACT2 may be recessed to a certain depth by the bit line trench region BTR. The bit line trench region BTR may not vertically overlap the second edge portion E2 of the first and second active patterns ACT1 and ACT2.

A plurality of bit line trench regions BTR may be provided. The plurality of bit line trench regions BTR may be spaced apart from each other in the first direction D1. The bit line trench regions BTR adjacent to each other in the first direction D1 may be spaced apart with the lower storage node contact BCx or the fence pattern FN interposed therebetween.

The bit line BL may be provided on the first edge portion E1 of the first and second active patterns ACT1 and ACT2 in the bit line trench region BTR and may extend in the fourth direction D4. A lower surface of the bit line BL may be positioned at a lower level than an upper surface of the second edge portion E2 of each of the first and second active patterns ACT1 and ACT2. The bit line BL may be positioned repeatedly in the first direction D1 to form a plurality of bit lines BL. The bit lines BL may be spaced apart from each other in the first direction D1 and may each extend in the fourth direction D4.

The bit line BL may be a composite layer containing two or more materials. As an example, the bit line BL may include a lower bit line BLx and an upper bit line BLy. The upper bit line BLy may extend in the fourth direction D4. The lower bit line BLx may be interposed between the upper bit line Bly and the first edge portion E1 of each of the first and second active patterns ACT1 and ACT2.

As an example, the lower bit line BLx may include at least one of a first barrier pattern (not shown) that prevents diffusion of a material of the upper bit line Bly, and a first silicide pattern (not shown) that improves contact resistance between the upper bit line BLy and the first edge portion E1 of each of the first and second active patterns ACT1 and ACT2. As an example, the lower bit line BLx may include or may be formed of metal silicide (e.g., silicide of Ti, Mo, W, Cu, Al, Ta, Ru, Ir, Co, etc.) and metal nitride (e.g., nitride of Ti, Mo, W, Cu, Al, Ta, Ru, Ir, Co, etc.). As an example, the upper bit line BLy may include metal (e.g., Ti, Mo, W, Cu, Al, Ta, Ru, Ir, Co, etc.).

The bit line BL may be in contact with the first edge portion E1 of each of the first and second active patterns ACT1 and ACT2. Accordingly, electrical resistance between the bit line BL and the first edge portion E1 of each of the first and second active patterns ACT1 and ACT2 may be reduced, thereby improving electrical characteristics of the semiconductor device.

Referring to FIG. 1B, the first bit line BL1 may extend in the fourth direction D4 on the first edge portion E1 of each of the first pattern PT1 and the third pattern PT3 of the first active pattern ACT1. The second bit line BL2 may extend in the fourth direction D4 on the first edge portion E1 of each of the first pattern PT1 and the second pattern PT2 of the second active pattern ACT2. The third bit line BL3 may extend in the fourth direction D4 on the first edge portion E1 of each of the second pattern PT2 and the fourth pattern PT4 of the first active pattern ACT1.

Again, referring to FIGS. 1A to 1C and 2A to 2D, a bit line capping pattern BCP may be provided on an upper surface of the bit line BL in the bit line trench region BTR. The bit line capping pattern BCP may extend in the fourth direction D4 along with the bit line BL. The bit line capping pattern BCP may be positioned repeatedly in the first direction D1 to form a plurality of bit line capping patterns BCP. The plurality of bit line capping patterns BCP may be spaced apart from each other in the first direction D1. The bit line capping pattern BCP may be composed of a single layer or multiple layers. As an example, the bit line capping pattern BCP may include a first capping pattern, a second capping pattern, and a third capping pattern that are sequentially stacked on each other. As an example, each of the first to third capping patterns may include silicon nitride (SiN). As another example, the bit line capping pattern BCP may include capping patterns stacked in four or more layers.

A bit line spacer BSP may be provided in the bit line trench region BTR. For example, the bit line spacer BSP may be disposed on a side surface of the bit line BL and on a side surface of the bit line capping pattern BCP. The bit line spacer BSP may cover the side surface of the bit line BL, the side surface of the bit line capping pattern BCP, and an inner side surface of the bit line trench region BTR. The bit line spacer BSP may further cover a side surface of the lower storage node contact BCx. The bit line spacer BSP may extend in the fourth direction D4 on the side surface of the bit line BL. For example, an upper surface of the bit line spacer BSP may be positioned at substantially the same level as an upper surface of the buffer pattern BP. The bit line spacer BSP may be placed repeatedly in the first direction D1 to form a plurality of bit line spacers BSP. The plurality of bit line spacers BSP may be spaced apart from each other in the first direction D1. In one bit line trench region BTR, two bit line spacers BSP adjacent to each other in the first direction D1 may be spaced apart with one bit line BL interposed therebetween. As an example, the bit line spacer BSP may include or may be formed of at least one of silicon oxide (SiO₂), silicon nitride (SiN), silicon oxycarbide (SiOC), and silicon oxycarbonitride (SiOCN). The bit line spacer BSP may be a single layer formed of a single material or a composite layer containing two or more materials.

A mold pattern MP may be provided on the buffer pattern BP, bit line capping pattern BCP, and bit line spacer BSP. The mold pattern MP may surround a landing pad LP, which will be described later. The mold pattern MP may be interposed between adjacent landing pads LP. When viewed in a two-dimensional view, the mold pattern MP may have a mesh shape including contact holes CH, which will be described later. As an example, the mold pattern MP may include or may be formed of at least one of silicon oxide (SiO₂), silicon nitride (SiN), silicon oxycarbide (SiOC), and silicon oxycarbonitride (SiOCN).

A contact hole CH may be provided on the second edge portion E2 of each of the first and second active patterns ACT1 and ACT2. The contact hole CH may penetrate the mold pattern MP and the buffer pattern BP. An upper portion of the lower storage node contact BCx, an upper portion of the bit line capping pattern BCP, and an upper portion of the bit line spacer BSP may be recessed to a certain depth by the contact hole CH. The contact hole CH may be further shifted from the lower storage node contact BCx in the first direction D1 (or in a direction opposite to the first direction D1). A portion of the contact hole CH may vertically overlap the bit line BL. A portion of the contact hole CH may vertically overlap the lower storage node contact BCx. The contact hole CH may be positioned repeatedly to form a plurality of contact holes CH which are arranged in a row in the first direction D1 and in a zigzag shape in the fourth direction D4.

An upper storage node contact BCy may be provided in the contact hole CH. The upper storage node contact BCy may be provided on and in contact with the lower storage node contact BCx. As an example, the upper storage node contact BCy may include or may be formed of at least one of silicon (e.g., polysilicon containing impurities) and metal (e.g., Ti, Mo, W, Cu, Al, Ta, Ru, Ir, Co, etc.). Accordingly, in FIG. 2A where two upper storage node contacts BCy and two lower storage node contacts BCx are shown, the upper storage node contact BCy on the left may be electrically connected to the second edge portion E2 of the corresponding first active pattern ACT1 through the lower storage node contact BCx on the left, and the upper storage node contact BCy on the right may be electrically connected to the second edge portion E2 of the corresponding second active pattern ACT2 through the lower storage node contact BCx on the right. The upper storage node contact BCy may be further shifted from the lower storage node contact BCx in the first direction D1 (or a direction opposite to the first direction D1). A portion of the upper storage node contact BCy may vertically overlap the bit line BL. The upper storage node contact BCy may be in contact with the bit line capping pattern BCP and the bit line spacer BSP. The upper storage node contact BCy and the lower storage node contact BCx may constitute a storage node contact BC together.

The upper storage node contact BCy may be repeatedly positioned to form a plurality of upper storage node contacts BCy. Each of the plurality of upper storage node contacts BCy may be provided in a corresponding contact hole CH. The upper storage node contacts BCy may be spaced apart from each other in the first and fourth directions D1 and D4. The upper storage node contacts BCy may be arranged in a line in the first direction D1 along with the contact hole CH, and may be arranged in a zigzag shape in the fourth direction D4.

A landing pad LP may be provided in the contact hole CH and on the upper storage node contact BCy. The landing pad LP may vertically overlap the upper storage node contact BCy. As an example, the landing pad LP may include or may be formed of at least one metal (e.g., Ti, Mo, W, Cu, Al, Ta, Ru, Ir, Co, etc.). Accordingly, the landing pad LP may be electrically connected to the second edge portion E2 of the corresponding active patterns ACT1 and ACT2 through the corresponding upper storage node contact BCy and the corresponding lower storage node contact BCx. The landing pad LP may be placed repeatedly to form a plurality of landing pads LP. The plurality of landing pads LP may be spaced apart from each other in the first and fourth directions D1 and D4.

As an example, a second silicide pattern SC may be further provided between the landing pad LP and the upper storage node contact BCy. As an example, the second silicide pattern SC may include or may be formed of metal silicide (e.g., silicide such as Ti, Mo, W, Cu, Al, Ta, Ru, Ir, Co, etc.). As an example, a second barrier pattern (not shown) may be interposed between the landing pad LP and other components and may prevent diffusion of the landing pad LP material. As an example, the second barrier pattern may include or may be formed of metal nitride (e.g., nitride such as Ti, Mo, W, Cu, Al, Ta, Ru, Ir, Co, etc.).

A data storage pattern DSP may be provided on the landing pad LP. The data storage pattern DSP may be placed repeatedly to form a plurality of data storage patterns DSP. The plurality of data storage patterns DSP may be spaced apart from each other in the first and fourth directions D1 and D4. Each of the data storage patterns DSP may be electrically connected to the second edge portion E2 of the corresponding active patterns ACT1 and ACT2 through the corresponding landing pad LP and the corresponding storage node contact BC.

The data storage pattern DSP may be, for example, a capacitor including a lower electrode, a dielectric layer, and an upper electrode. In this case, the semiconductor device according to the inventive concept may be a dynamic random access memory (DRAM). As an example, the data storage pattern DSP may include a magnetic tunnel junction pattern. In this case, the semiconductor device according to the inventive concept may be a magnetic random access memory (MRAM). As an example, the data storage pattern DSP may include a phase change material or a variable resistance material. In this case, the semiconductor device according to the inventive concept may be a phase-change random access memory (PRAM) or a resistive random access memory (ReRAM). However, this is only an example and the inventive concept is not limited thereto, and the data storage pattern DSP may include various structures and/or materials capable of storing data.

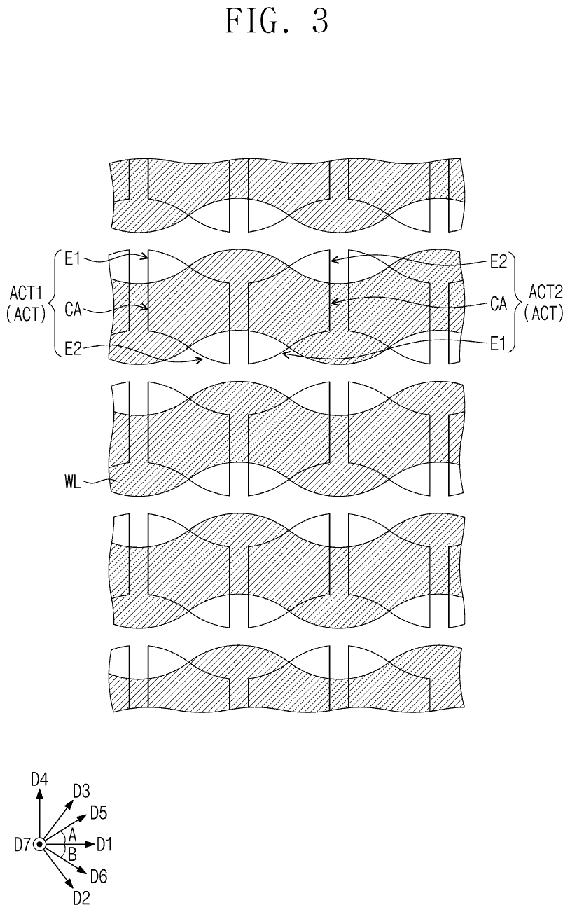

Below, various embodiments of the inventive concept will be described with reference to FIGS. 3 to 14D. To simplify the explanation, description of content that overlaps with the above-described content will be omitted, and the explanation will focus on the differences from the above-described content.

FIG. 3 is a plan view showing a semiconductor device according to some embodiments of the inventive concept.

Referring to FIG. 3, when viewed in a plan view, the first and second active patterns ACT1 and ACT2 may have profiles different from those described with reference to FIGS. 1A to 1C and 2A to 2D.

Each of the first active patterns ACT1 may extend in a wave shape in the second direction D2. Each of the second active patterns ACT2 may extend in a wave shape in the third direction D3.

Opposite sides of each of the first active patterns ACT1 may have a curved profile. Opposite sides of each of the second active patterns ACT2 may have a curved profile. Opposite sides of each of the first active patterns ACT1 may extend in a wave shape in the second direction D2. Opposite sides of each of the second active patterns ACT2 may extend in a wave shape in the third direction D3.

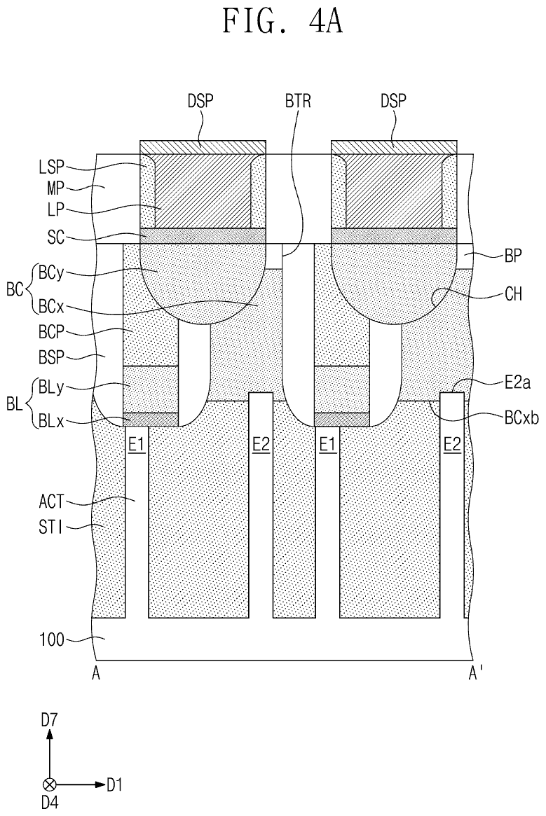

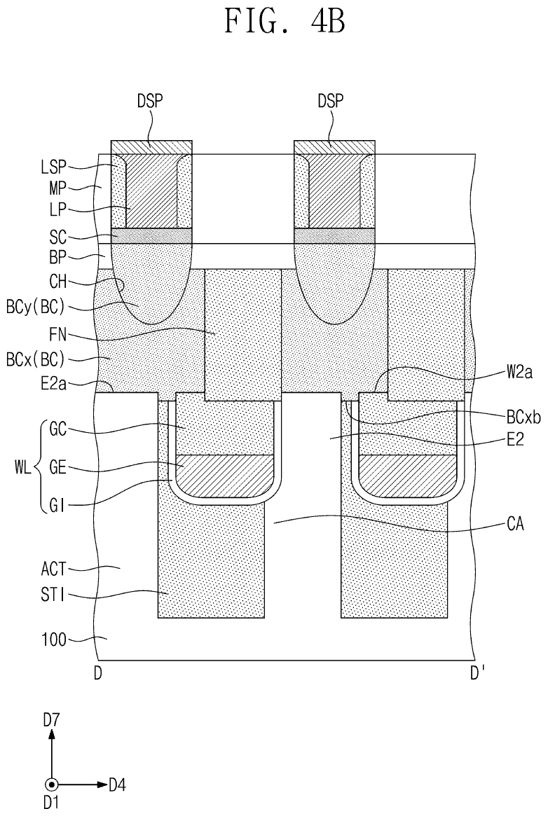

FIGS. 4A and 4B are cross-sectional views corresponding to lines A-A′ and D-D′ of FIG. 1A, respectively.

Referring to FIGS. 4A and 4B, a lower surface BCxb of the lower storage node contact BCx may be positioned at a lower level than an upper surface E2a of the second edge portion E2 of the first and second active patterns ACT1 and ACT2. The lower storage node contact BCx may cover an upper portion of the second edge portion E2 of the first and second active patterns ACT1 and ACT2. For example, the lower storage node contact BCx may be in contact with an upper surface and a side surface of the second edge portion E2 of the first and second active patterns ACT1 and ACT2. Accordingly, compared to the semiconductor device of FIGS. 2A to 2D, the contact area between the lower storage node contact BCx and the second edge portion E2 of the first and second active patterns ACT1 and ACT2 may be increased. As a result, the lower storage node contact BCx may be electrically connected to the second edge portion E2 of the first and second active patterns ACT1 and ACT2 with an increased contact area, and electrical characteristics of the semiconductor device may be improved.

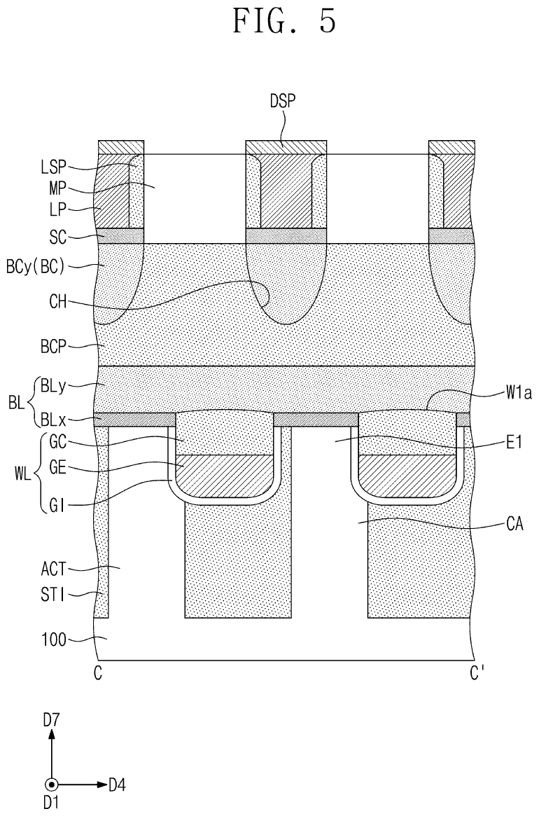

FIG. 5 is a cross-sectional view corresponding to line C-C′ in FIG. 1A.

Referring to FIG. 5, the word line WL may extend further into the bit line BL. As an example, the gate capping pattern GC may extend further into the bit line BL. The gate capping pattern GC may be interposed between the lower bit lines BLx in the fourth direction D4. A first upper surface W1a of the word line WL (e.g., an upper surface of the gate capping pattern GC) may be positioned at a higher level than an upper surface of the lower bit line BLx. Accordingly, a separation distance between the upper bit line BLy and the gate electrode GE may be increased, thereby reducing electrical interference between the upper bit line BLy and the gate electrode GE. As a result, electrical characteristics of the semiconductor device may be improved.

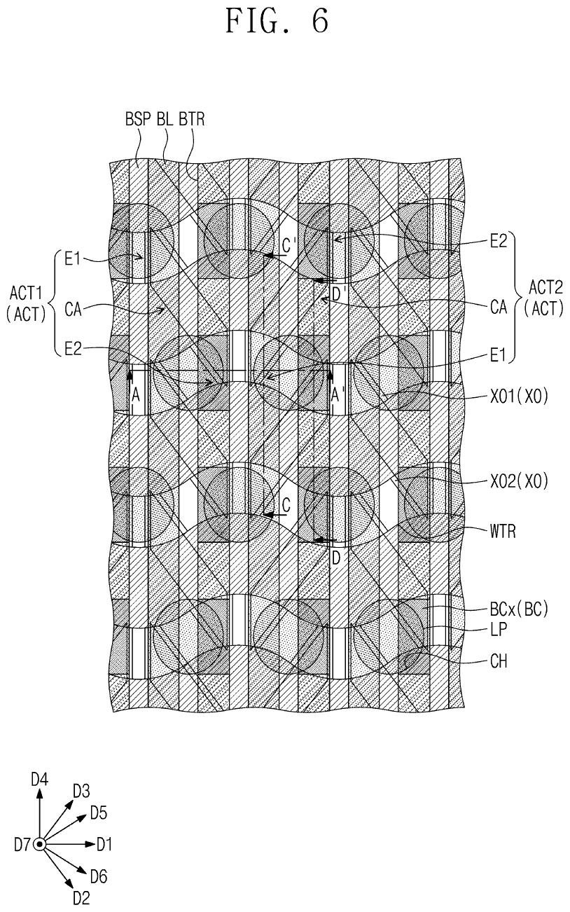

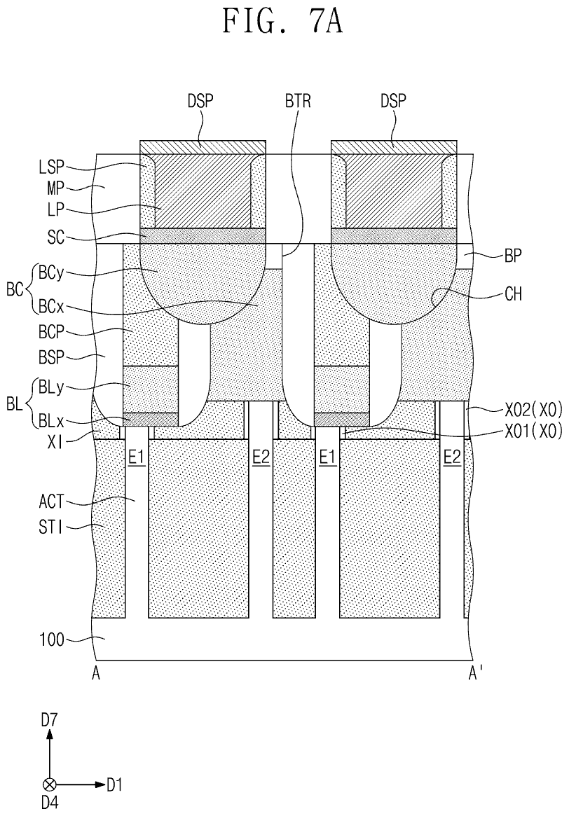

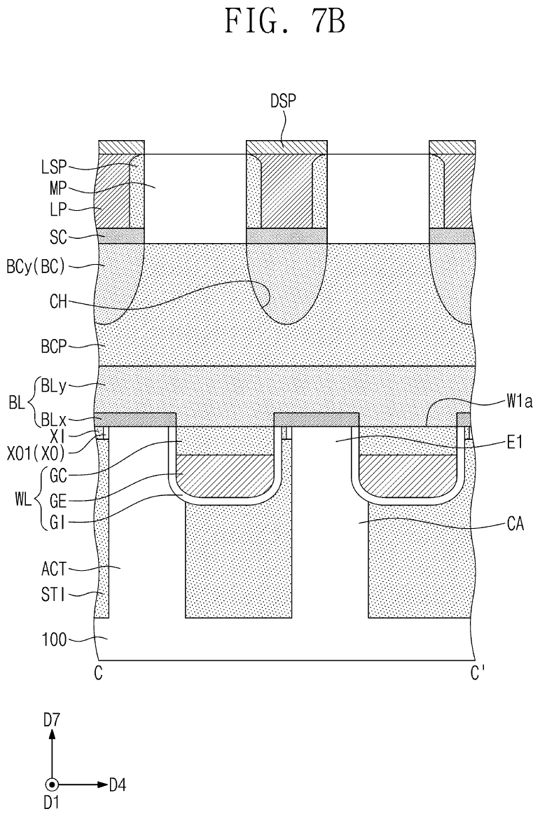

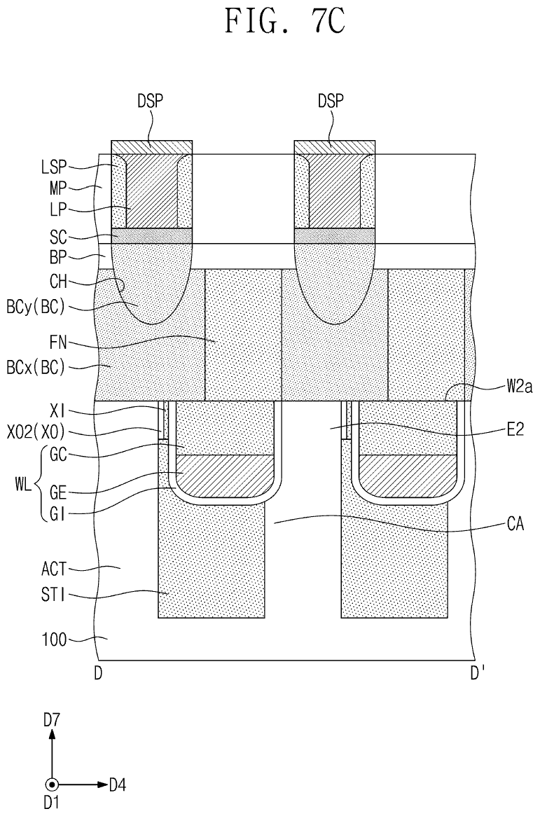

FIG. 6 is a plan view showing a semiconductor device according to some embodiments of the inventive concept. FIGS. 7A to 7C are cross-sectional views corresponding to lines A-A′, C-C′, and D-D′ of FIG. 6, respectively.

Referring to FIGS. 6 to 7C, an upper surface of each of the first and second edge portions E1 and E2 of the first and second active patterns ACT1 and ACT2 may be positioned at a higher level than an upper surface of the device isolation pattern STI.

An active pad XO may be disposed on an upper surface of the device isolation pattern STI and surround and cover side surfaces of the first and second edge portions E1 and E2 of the first and second active patterns ACT1 and ACT2. The active pad XO may include a first active pad XO1 surrounding and covering a side surface of the first edge portion E1 of the first and second active patterns ACT1 and ACT2, and a second active pad XO2 surrounding and covering a side surface of the second edge portion E2 of the active pattern ACT1 and ACT2. The active pad XO may include an impurity region doped with impurities (e.g., n-type or p-type impurities) therein. The impurity region of the active pad XO and the impurity region of the first and second active patterns ACT1 and ACT2, may constitute a source drain region and/or a channel region of the transistor. Accordingly, when viewed in a two-dimensional view, the area of the source drain region of the transistor may be increased. For example, the active pad XO may include the same material as the first and second active patterns ACT1 and ACT2. As an example, the active pad XO may include or may be formed of at least one of silicon (e.g., single crystal silicon), germanium, and silicon-germanium doped with impurities (e.g., n-type or p-type impurities).

A pad insulation pattern XI may be provided on an upper surface of the device isolation pattern STI. The pad insulation pattern XI may be interposed between the first and second active pads XO1 and XO2. The pad insulation pattern XI may include or may be formed of an insulating material. As an example, the pad insulation pattern XI may include or may be formed of at least one of silicon oxide (SiO₂) and silicon nitride (SiN).

The bit line BL may be in contact with the first active pad XO1. The bit line BL may be electrically connected to the first active pad XO1 and the first edge portion E1 of the first and second active patterns ACT1 and ACT2. The first active pad may be provided to increase the contact area between the bit line BL and the source drain region, thereby lowering contact resistance.

The lower storage node contact BCx may be in contact with the second active pad XO2. The storage node contact BC may be electrically connected to the second active pad XO2 and the second edge portion E2 of the first and second active patterns ACT1 and ACT2. The second active pad XO2 may be provided to increase the contact area between the storage node contact BC and the source drain region, thereby lowering contact resistance therebetween.

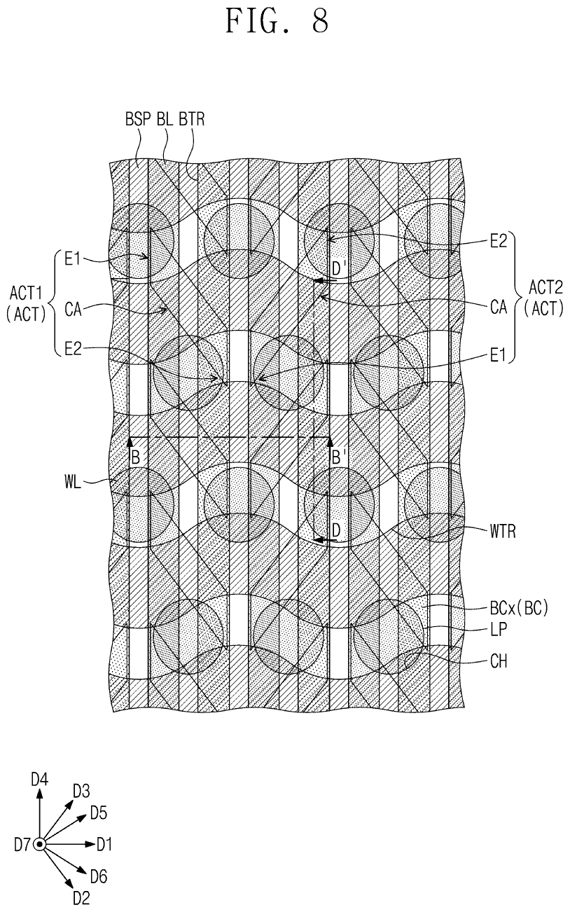

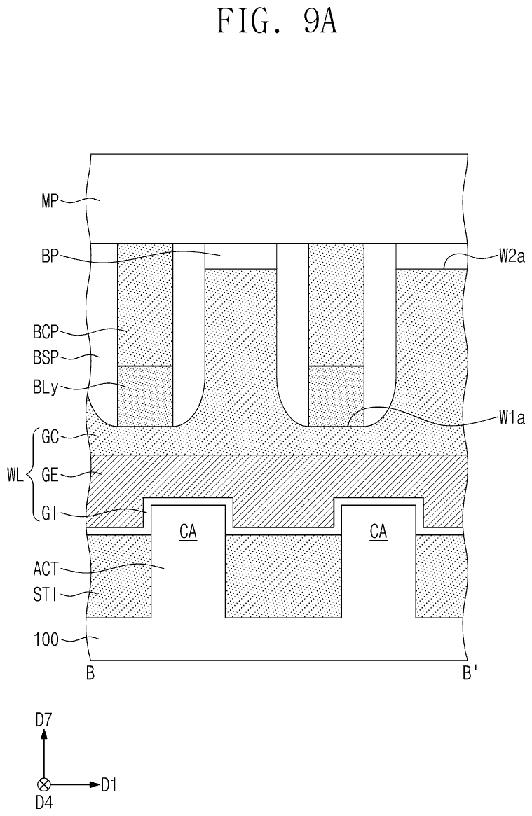

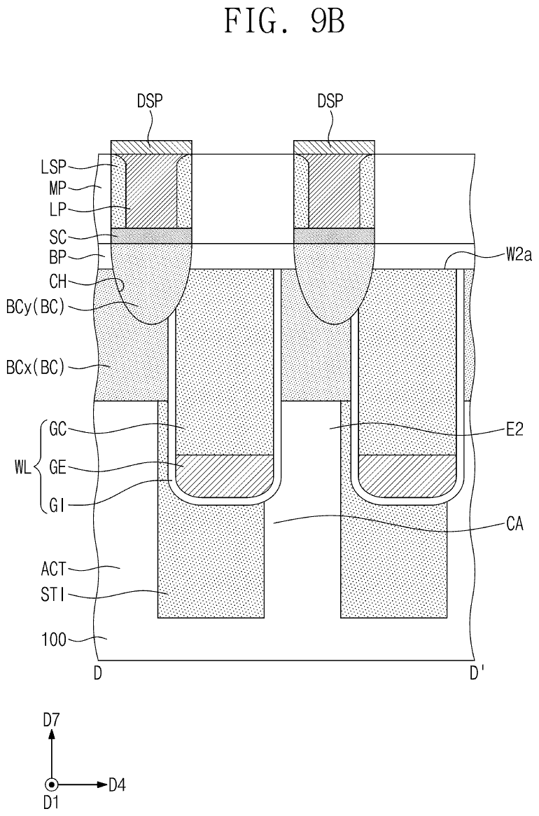

FIG. 8 is a plan view showing a semiconductor device according to some embodiments of the inventive concept. FIGS. 9A and 9B are cross-sectional views corresponding to lines B-B′ and D-D′ of FIG. 8, respectively.

Referring to FIGS. 8 to 9B, the fence pattern FN may not be provided. The word line WL may extend in the first direction D1 and a seventh direction D7 perpendicular to a lower surface of the substrate 100 between the lower storage node contacts BCx adjacent to each other in the fourth direction D4. A second upper surface W2a of the word line WL may be positioned at substantially the same level as an upper surface of the lower storage node contact BCx. The word line WL may be in contact with the buffer pattern BP. The word lines WL may be spaced apart in the fourth direction D4 with the lower storage node contact BCx interposed therebetween.

The bit line trench region BTR may be provided in the word line WL (e.g., in the gate capping pattern GC). The bit line trench region BTR may cross the word line WL in the fourth direction D4. In one word line WL, the bit line trench regions BTR may be spaced apart in the first direction D1.

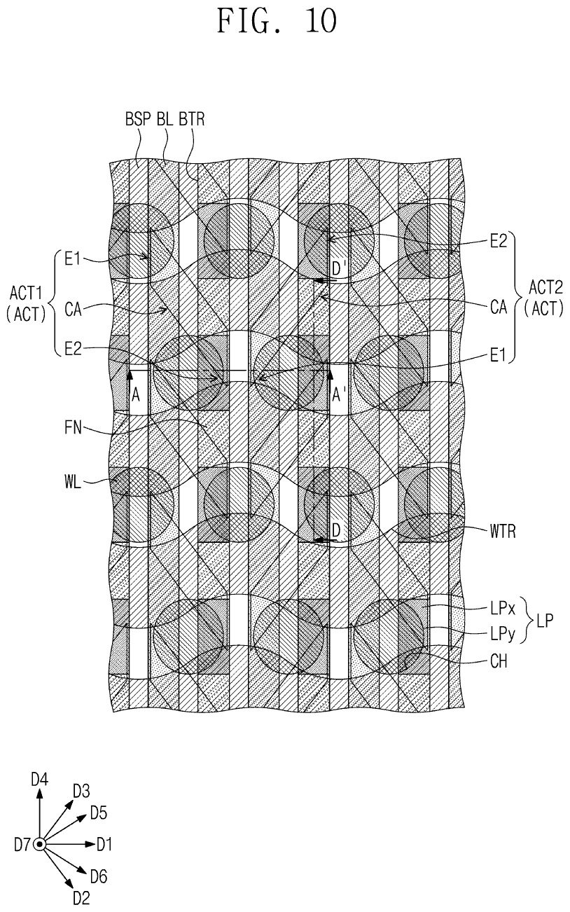

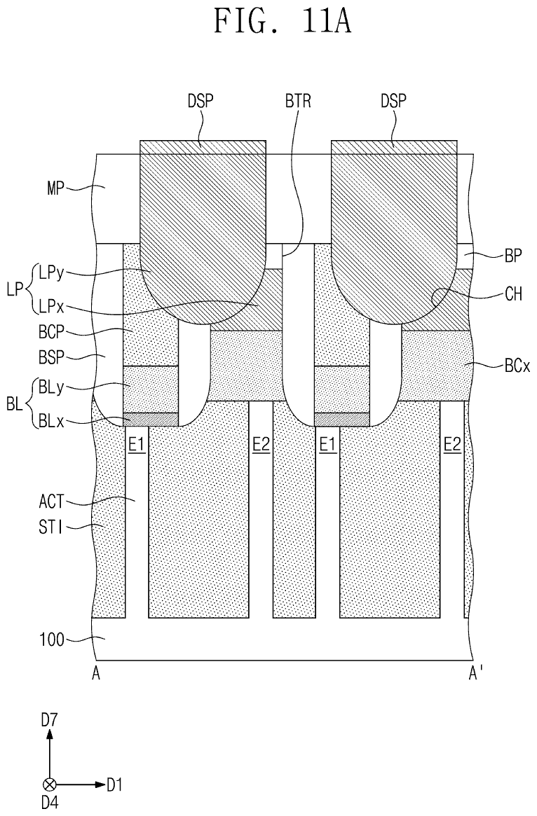

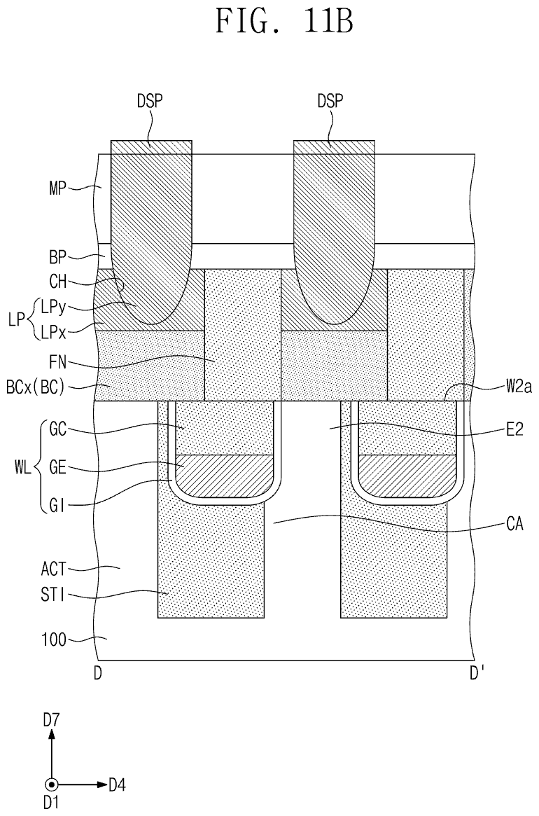

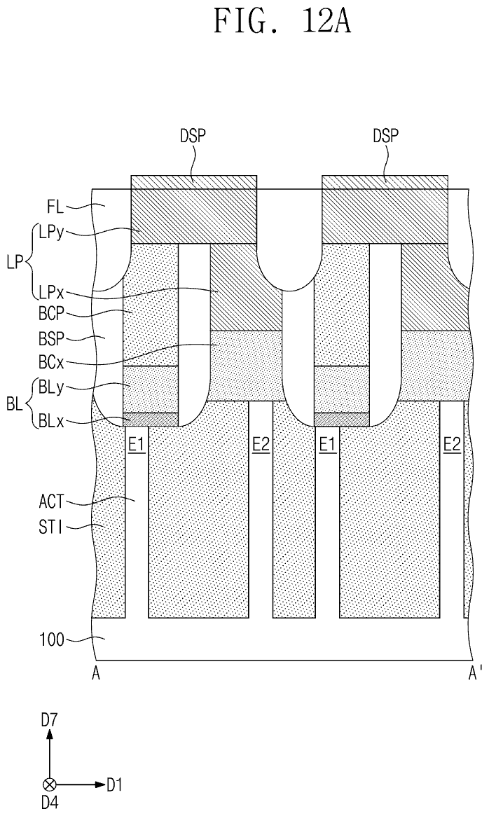

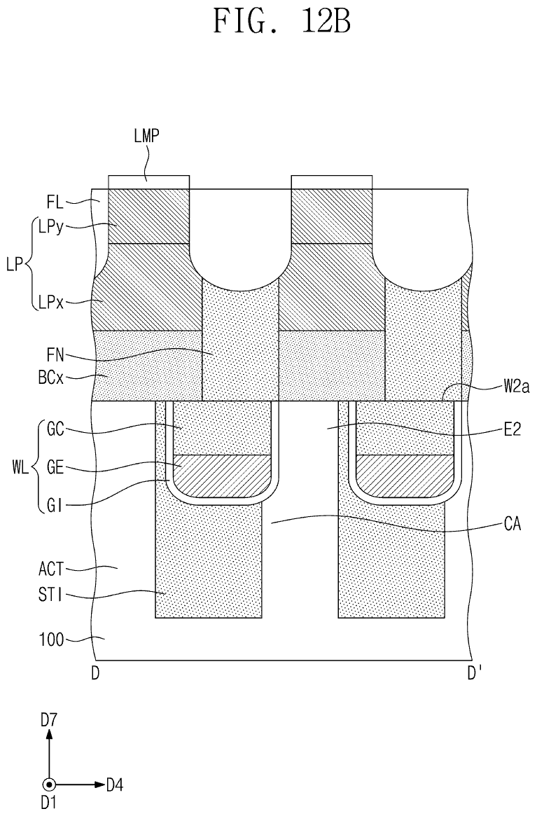

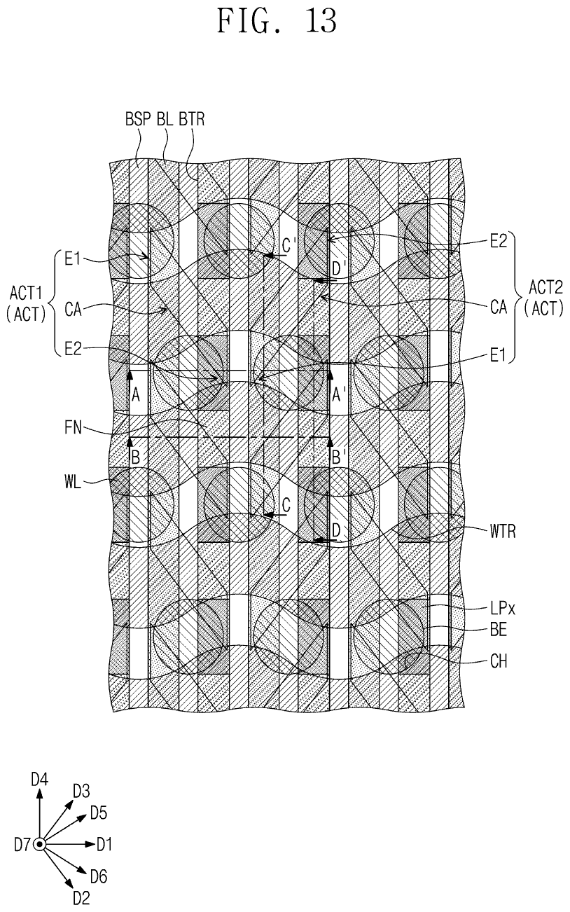

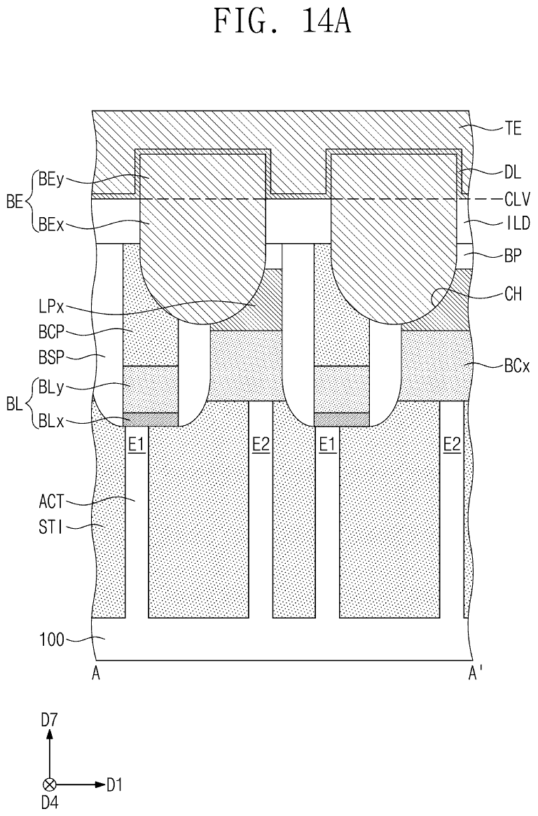

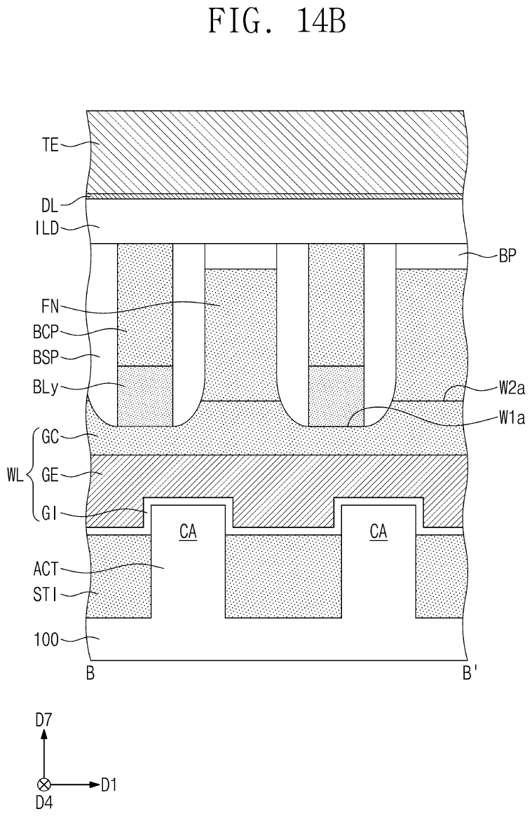

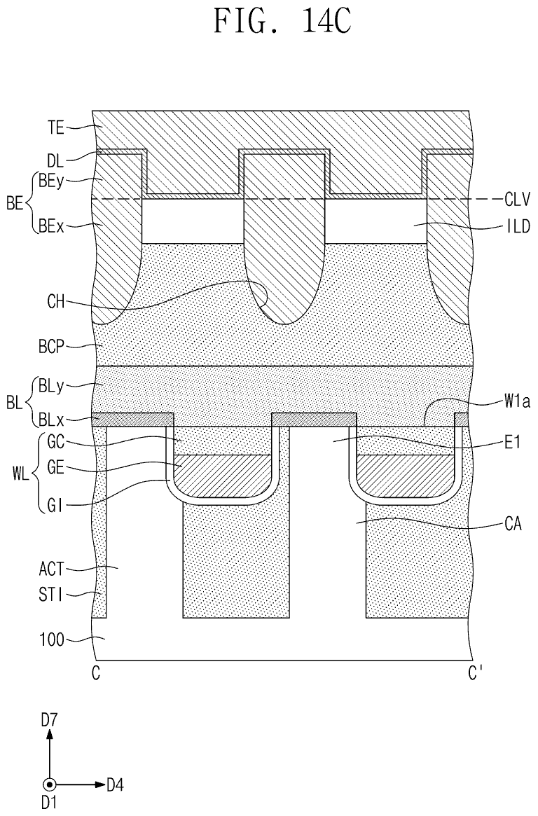

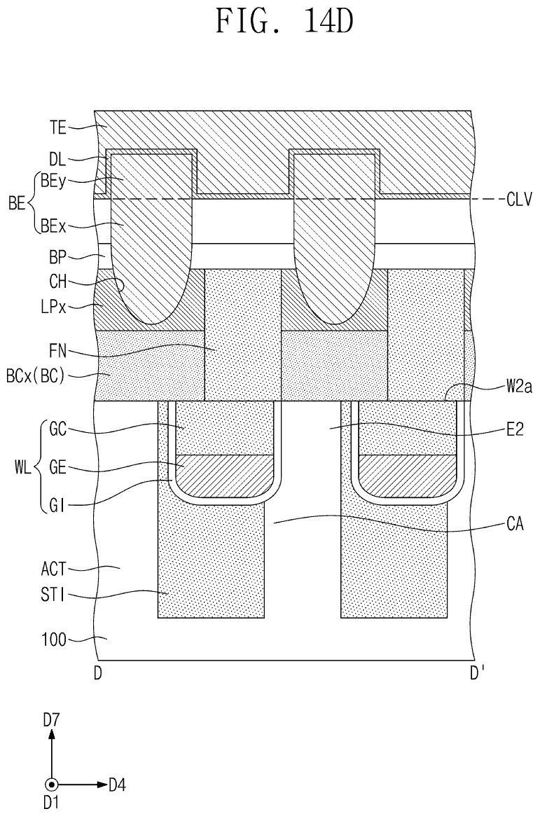

FIGS. 10 and 13 are plan views respectively showing semiconductor devices according to some embodiments of the inventive concept. FIGS. 11A and 11B are cross-sectional views corresponding to lines A-A′ and D-D′ of FIG. 10, respectively. FIGS. 12A and 12B are cross-sectional views corresponding to lines A-A′ and D-D′ of FIG. 10, respectively. FIGS. 14A to 14D are cross-sectional views corresponding to lines A-A′, B-B′, C-C′, and D-D′ of FIG. 13, respectively.

Referring to FIGS. 10 to 14D, a lower landing pad LPx may be provided on the lower storage node contact BCx. As an example, the lower landing pad LPx may be in contact with an upper surface of the lower storage node contact BCx. Referring to FIGS. 10 to 11B and 13 to 14D, the lower landing pad LPx may be interposed between the buffer pattern BP and the lower storage node contact BCx. The lower landing pad LPx may be interposed between neighboring bit line capping patterns BCP in the first direction D1. The lower landing pad LPx may be interposed between neighboring fence patterns FN in the fourth direction D4.

The lower landing pad LPx may be positioned repeatedly to form a plurality of lower landing pads LPx. The plurality of lower landing pads LPx may be spaced apart from each other in the first and fourth directions D1 and D4. The lower landing pads LPx adjacent to each other in the first direction D1 may be spaced apart from each other with the bit line capping pattern BCP interposed therebetween. The lower landing pads LPx adjacent to each other in the fourth direction D4 may be spaced apart with the fence pattern FN interposed therebetween.

Referring to FIGS. 10 to 11B, an upper landing pad LPy may fill the inside of the contact hole CH. The upper storage node contact BCy and the second silicide pattern SC may not be provided in the contact hole CH. The upper landing pad LPy may be in contact with the bit line capping pattern BCP and the bit line spacer BSP. The upper landing pad LPy may be in contact with the lower landing pad LPx at a level lower than a lower surface of the mold pattern MP.

Referring to FIGS. 10, 12A, and 12B, the mold pattern MP and contact holes CH may not be provided. An upper landing pad LPy may be provided on the lower landing pad LPx. The upper landing pad LPy may be shifted in the first direction D1 (or the opposite direction) compared to the lower landing pad LPx. A portion of the upper landing pad LPy may vertically overlap the bit line BL. The upper landing pad LPy may be positioned repeatedly to form a plurality of upper landing pads LPy. The upper landing pads LPy may be arranged in a line in the first direction D1 and in a zigzag shape in the fourth direction D4.

The upper landing pad LPy and the lower landing pad LPx may constitute a landing pad LP. The landing pad LP may include or may be formed of a conductive material.

A filling pattern FL may surround the upper landing pads LP. The filling pattern FL may be interposed between adjacent upper landing pads LPy. When viewed in a plan view, the filling pattern FL may have a mesh shape including holes penetrated by the upper landing pads LPy. As an example, the filling pattern FL may include or may be formed of at least one of silicon nitride, silicon oxide, and silicon oxynitride. As an example, the filling pattern FL may include an empty space containing an air layer (i.e., an air gap). The term “air” as discussed herein, may refer to atmospheric air, or other gases that may be present during the manufacturing process.

Referring to FIGS. 13 and 14A to 14D, the mold pattern MP may not be provided. An interlayer insulating layer ILD may be provided on the entire surface of the substrate 100. In detail, the interlayer insulating layer ILD may be provided on the bit line capping pattern BCP and buffer pattern BP. The interlayer dielectric layer ILD may include or may be formed of at least one of silicon nitride, silicon oxide, or silicon oxynitride. As an example, the interlayer insulating layer ILD may include an empty region. The contact holes CH may penetrate the interlayer insulating layer ILD, and the interlayer insulating layer ILD may have a mesh shape including the contact holes CH, when viewed in a plan view.

A lower electrode BE may be provided on the lower landing pad LPx. The lower electrode BE may include a lower portion BEx below a contact level CLV and an upper portion BEy above the contact level CLV. The contact level CLV is defined as the level at which an upper surface of the interlayer dielectric layer ILD is positioned. For example, a lower portion BEx and an upper portion BEy of the lower electrode BE may be divided from each other at the contact level CLV without an interface at the contact level CLV, but are not limited thereto.

The lower portion BEx of the lower electrode BE may be provided in the contact hole CH. The lower portion BEx of the lower electrode BE may fill the inside of the contact hole CH. The lower portion BEx of the lower electrode BE may be in contact with the bit line capping pattern BCP, the bit line spacer BSP, and the lower landing pad LPx. The lowermost surface of the lower portion BEx of the lower electrode BE may be positioned at a lower level than an upper surface of the lower landing pad LPx.

The upper portion BEy of the lower electrode BE may be provided on the lower portion BEx of the lower electrode BE. For example, the upper portion BEy of the lower electrode BE may have a pillar shape. As an example, although not shown, the upper portion BEy of the lower electrode BE may have a shape of a hollow cylinder with one end closed. According to some embodiments, although not shown, the upper portion BEy of the lower electrode BE may have a pillar-shaped lower portion and a hollow cylinder-shaped upper portion.

The lower electrode BE may be positioned repeatedly to form a plurality of lower electrodes BE. The lower electrodes BE may be spaced apart from each other in the first and fourth directions D1 and D4. When viewed in a plan view, for example, the lower electrodes BE may be arranged to have a honeycomb shape. In detail, with one lower electrode BE at the center, six lower electrodes BE may be arranged to surround the one lower electrode BE in a hexagonal arrangement. However, the inventive concept is not limited to this.

An upper electrode TE may be provided on the lower electrode BE. In detail, the upper electrode TE may cover an upper surface of the upper BEy of the lower electrode BE, and may surround and cover a side surface of the upper BEy of the lower electrode BE. The upper electrode TE may fill a space between the upper portions BEy of the lower electrodes BE.

Each of the lower electrode BE and the upper electrode TE may include or may be formed of a conductive material. As an example, each of the lower electrode BE and the upper electrode TE may include or may be formed of at least one of impurity-doped silicon (Si), impurity-doped silicon germanium (SiGe), a metal material (e.g., Ti, Mo, W, Cu, Al, Ta, Ru, Ir, Co, Pt, Au, Ag, etc.), metal nitride (e.g., nitride of Ti, Mo, W, Cu, Al, Ta, Ru, Ir, Co, Pt, Au, Ag, etc.), titanium silicon nitride (e.g. TiSiN), titanium aluminum nitride (e.g. TiAlN), tantalum aluminum nitride (e.g. TaAlN), etc.), conductive oxide (e.g. PtO, RuO₂, IrO₂, SrRuO₃ (SRO), (Ba,Sr)RuO₃ (BSRO), CaRuO₃ (CRO), LSCo), and metal silicide. Each of the lower electrode BE and the upper electrode TE may be a single layer formed of a single material or a composite layer containing two or more materials.

A dielectric layer DL may be interposed between each of the upper portions BEy of the lower electrodes BE and the upper electrode TE, and between the upper electrode TE and the interlayer insulating layer ILD. The dielectric layer DL may conformally cover the upper portions BEy of the lower electrodes BE. As an example, the dielectric layer DL may include or may be formed of at least one of metal oxides such as HfO₂, ZrO₂, Al₂O₃, La₂O₃, Ta₂O₃, and TiO₂, and a perovskite-structured dielectric material such as SrTiO₃ (STO), (Ba,Sr)TiO₃ (BST), BaTiO₃, PZT, and PLZT.

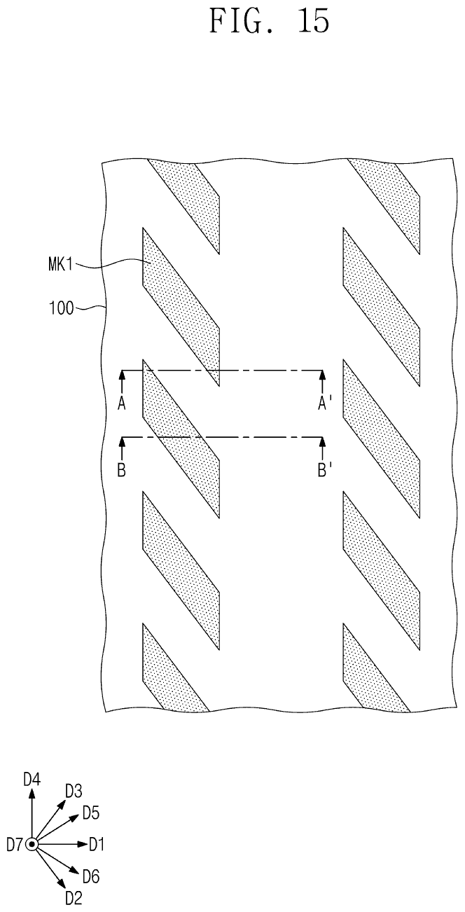

Hereinafter, a method of manufacturing a semiconductor device according to some embodiments of the inventive concept will be described with reference to FIGS. 15 to 31B. To simplify the explanation, description of content that overlaps with the above-described content will be omitted, and the explanation will focus on the differences from the above-described content.

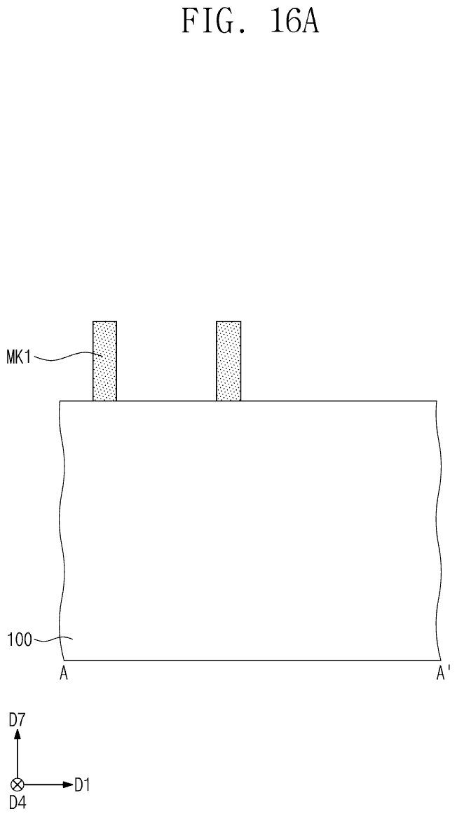

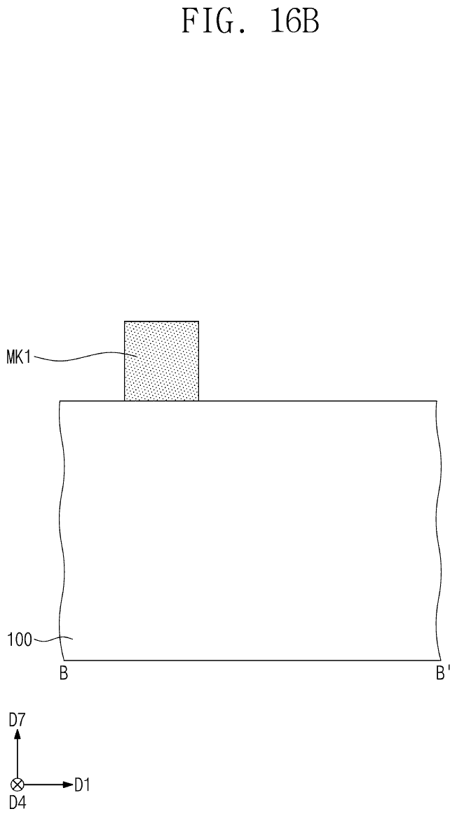

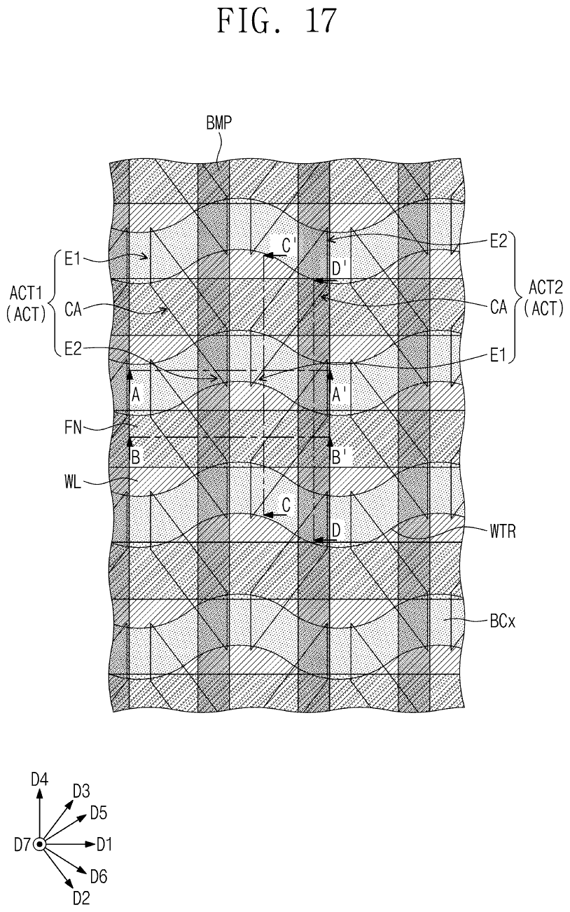

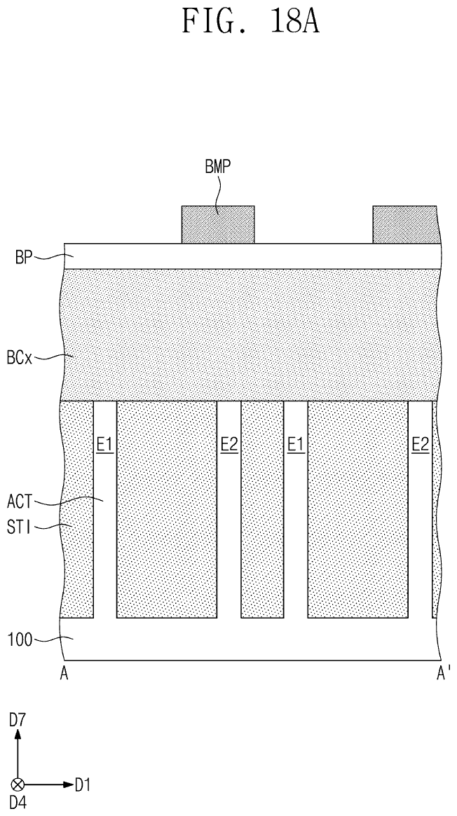

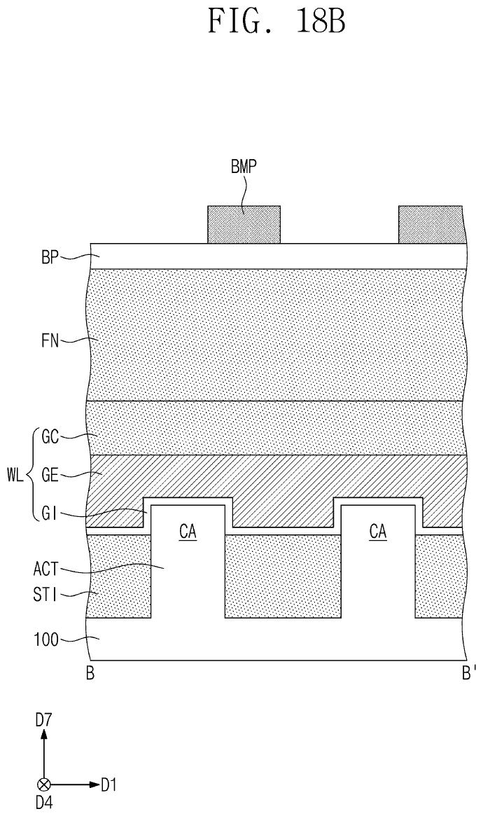

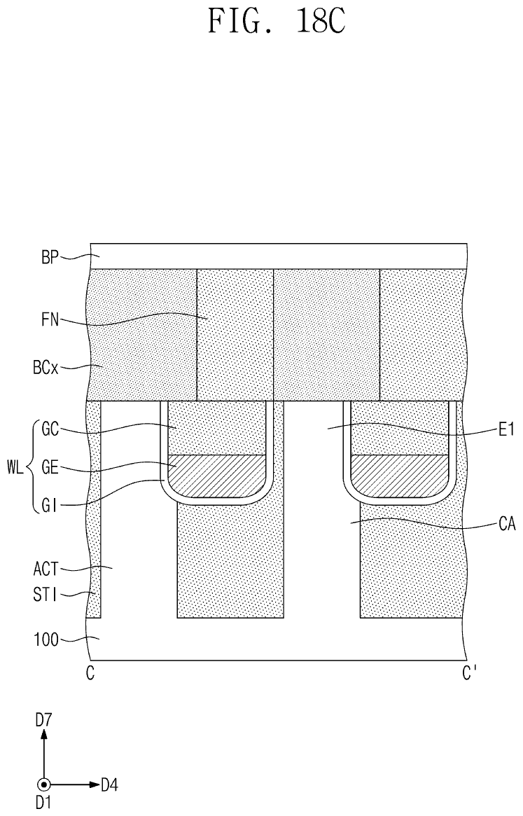

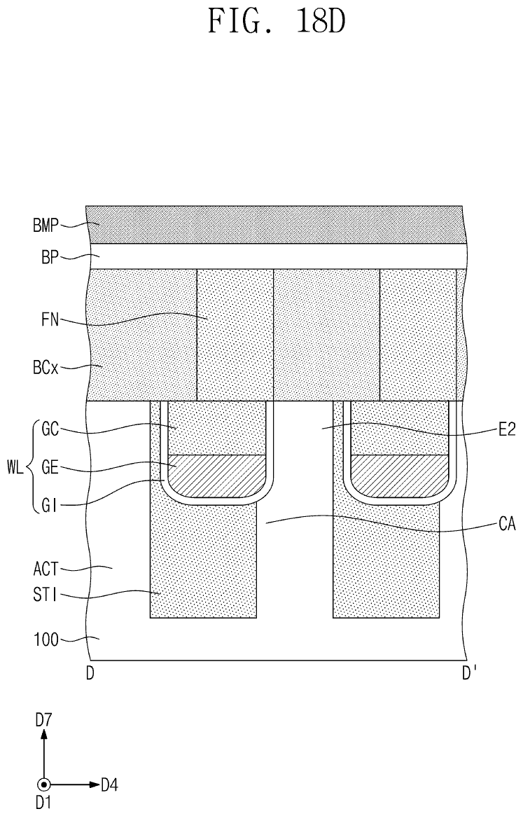

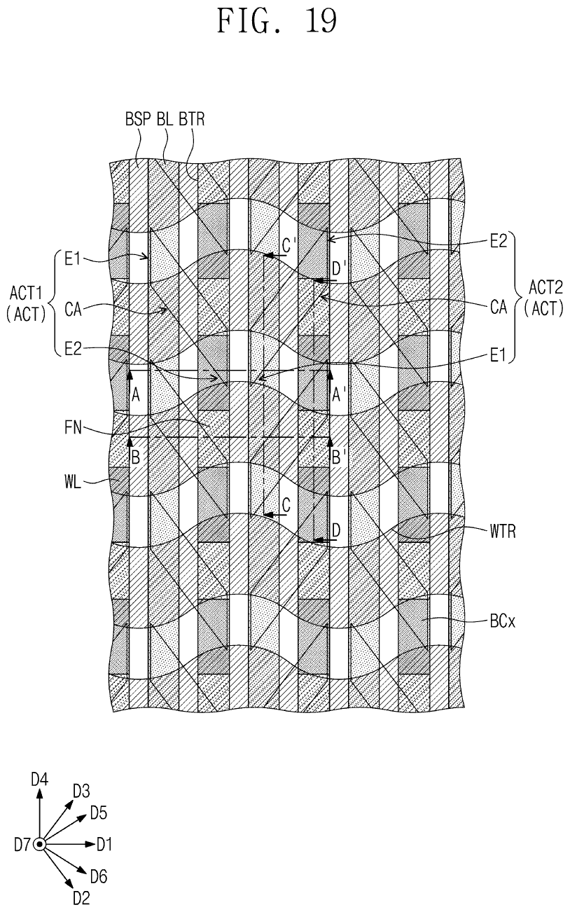

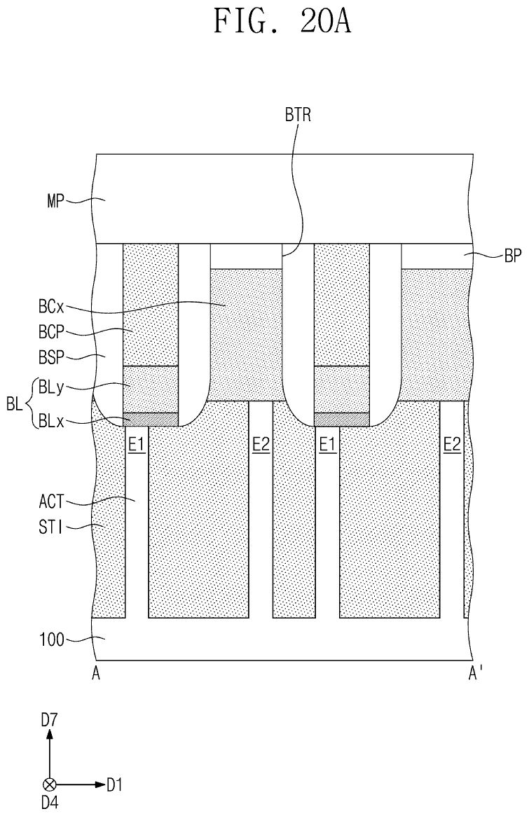

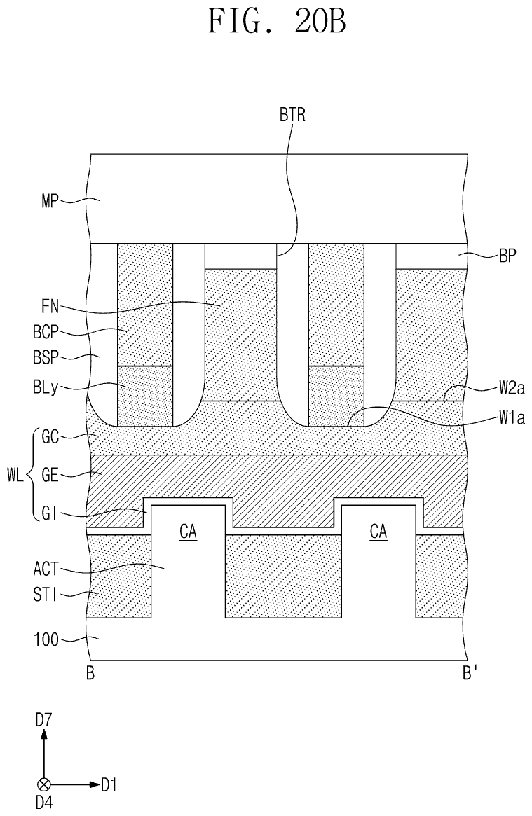

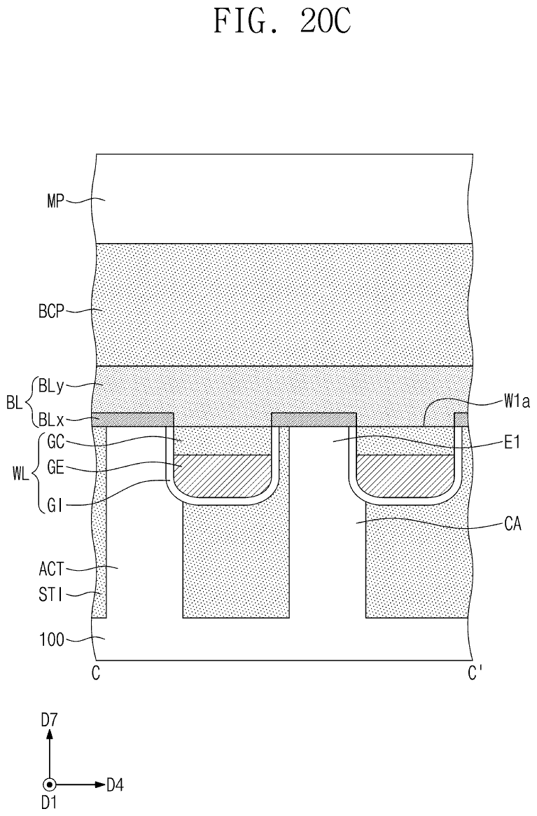

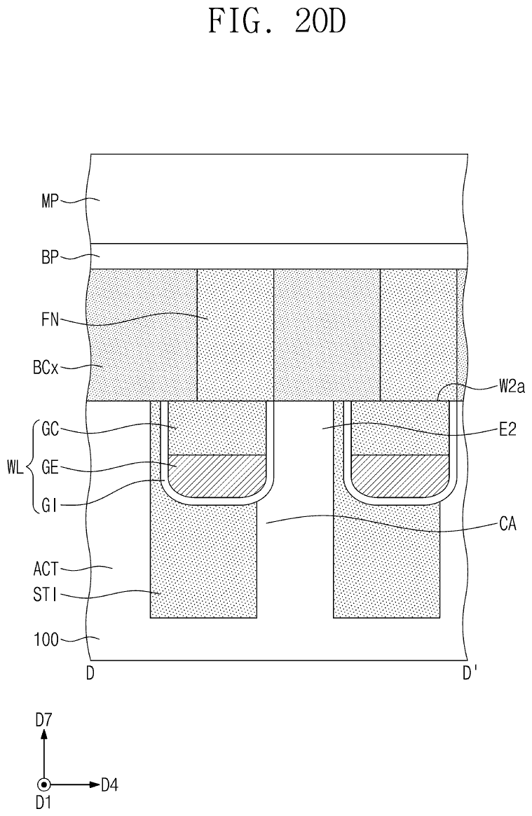

FIGS. 15 to 20D are diagrams showing a method of manufacturing a semiconductor device according to some embodiments of the inventive concept. In detail, FIGS. 15, 17, and 19 are plan views showing a method of manufacturing a semiconductor device according to some embodiments of the inventive concept. FIGS. 16A, 18A, and 20A are cross-sectional views corresponding to line A-A′ of FIGS. 15, 17, and 19, respectively. FIGS. 16B, 18B, and 20B are cross-sectional views corresponding to line B-B′ of FIGS. 15, 17, and 19, respectively. FIGS. 18C and 20C are cross-sectional views corresponding to line C-C′ of FIGS. 17 and 19, respectively. FIGS. 18D and 20D are cross-sectional views corresponding to line D-D′ of FIGS. 17 and 19, respectively.

Referring to FIGS. 15 to 16B, a substrate 100 may be prepared. First active mask patterns MK1 may be formed on the substrate 100. Each of the first active mask patterns MK1 may be formed to extend lengthwise in the second direction D2. When viewed in a two-dimensional view, each of the first active mask patterns MK1 may be formed to have an identical/similar shape of the first active pattern ACT1 as described with reference to FIGS. 1A to 2D. An arrangement manner of the first active mask patterns MK1 may be the same/similar to the arrangement manner of the first active patterns ACT1 described with reference to FIGS. 1A to 2D.

Referring to FIGS. 17 to 18D, a removal process on the substrate 100 may be performed using the first active mask patterns MK1 as an etch mask. Accordingly, first active patterns ACT1 may be formed on the substrate 100.

Second active mask patterns (not shown) may be formed on the substrate 100. Each of the second active mask patterns may be formed to extend lengthwise in a third direction D3. When viewed in a plan view, the second active mask pattern may be formed adjacent to the first active pattern ACT1 in a first direction D1. When viewed in a plan view, each of the second active mask patterns may have the same/similar shape of the second active pattern ACT2 as described with reference to FIGS. 1A to 2D. An arrangement manner of the second active mask patterns may be the same/similar to the arrangement manner of the second active patterns ACT2 described with reference to FIGS. 1A to 2D.

A removal process on the substrate 100 may be performed using the second active mask patterns as an etch mask. Accordingly, second active patterns ACT2 may be formed on the substrate 100.

Profiles of the first and second active patterns ACT1 and ACT2 may be formed in various ways depending on a profile and arrangement of the first active mask pattern MK1 and the second active mask pattern MK1. For example, depending on the profile and arrangement of the first active mask pattern MK1 and the second active mask pattern, the first and second active patterns ACT1 and ACT2 may have the profiles as shown in FIG. 3.

A device isolation pattern STI may be formed on the substrate 100 to surround each of the first and second active patterns ACT1 and ACT2.

A word line WL may be formed to cross the first and second active patterns ACT1 and ACT2 and the device isolation pattern STI. Forming the word line WL may include forming a mask pattern on the first and second active patterns ACT1 and ACT2 and device isolation patterns STI, anisotropic etching process using the mask pattern to form a word line trench region WTR crossing the first and second active patterns ACT1 and ACT2 and the device isolation pattern STI, and filling the word line trench region WTR with a word line WL. The word line WL may be formed on the center portion CA of the first and second active patterns ACT1 and ACT2 and may be formed between the first edge portion E1 and the second edge portion E2.

The word line trench region WTR may be formed to extend in a wave shape in the first direction D1. Accordingly, the word line WL filling the word line trench region WTR may be formed to have a wave shape extending in the first direction D1.

The formation of the word line WL may include, for example, conformally depositing a gate dielectric pattern GI on an inner surface of the word line trench region WTR, filling the inner space of the word line trench region WTR with a conductive layer, forming a gate electrode GE through an planarization process such as an etch-back and/or polishing process on the conductive layer, and filling the remainder of the word line trench region WTR on the gate electrode GE to form a gate capping pattern GC.

Lower storage node contacts BCx and fence patterns FN may be formed to be alternately arranged in the fourth direction D4 on the substrate 100. The lower storage node contacts BCx may be formed to extend in the first direction D1 and may be disposed on the second edge portions E2 of the first and second active patterns ACT1 and ACT2. The fence patterns FN may be formed to extend in the first direction D1 and may be disposed on the center portion CA of the first and second active patterns ACT1 and ACT2. For example, the formation of the lower storage node contacts BCx and the fence patterns FN may include forming a lower storage node contact layer (not shown) to cover the entire surface of the substrate 100, and forming the fence pattern FN such that the lower storage node contact layer is separated into a plurality of lower storage node contacts BCx spaced apart from each other in the fourth direction D4. Thereafter, a buffer pattern BP may be formed to cover the entire surface of the substrate 100.

As an example, although not shown in the drawing, a removal process may be performed on an upper portion of each of the device isolation pattern STI and gate dielectric pattern GI after the forming of the word line WL and before the forming of the lower storage node contact layer. Each of the device isolation pattern STI and the gate dielectric pattern GI may have etch selectivity with respect to surrounding components (e.g., active patterns ACT1 and ACT2 and gate capping pattern GC, etc.). Accordingly, when the removal process proceeds, surrounding components may not be removed or may be removed to a small extent. Accordingly, upper side surfaces of the first and second edge portions E1 and E2 of the first and second active patterns ACT1 and ACT2 may be exposed to the outside. Thereafter, as described above, the lower surface of the lower storage node contact BCx may be formed to be positioned at a lower level than the upper surface of each of the first and second edge portions E1 and E2 of the first and second active patterns ACT1 and ACT2. Accordingly, a semiconductor device may be formed to have the characteristics described with reference to FIGS. 4A and 4B.

A bit line mask pattern BMP may be formed on the buffer pattern BP. The bit line mask pattern BMP may include a plurality of mask patterns spaced apart from each other in the first direction D1 and each extending in the fourth direction D4. The bit line mask pattern BMP may be formed on the second edge portion E2 of the first and second active patterns ACT1 and ACT2.

Referring to FIGS. 19 to 20D, bit line trench regions BTR may be formed through an etching process using the bit line mask pattern BMP as an etch mask. Through the etching process, the buffer pattern BP, the lower storage node contact BCx, the fence pattern FN, an upper portion of the word line WL, and an upper portion the first edge portion E1 of the first and second active patterns ACT1 and ACT2 may be removed, and the bit line trench regions BTR may be defined in the regions from where they have been removed. The bit line trench regions BTR may be formed on the first edge portions E1 of the first and second active patterns ACT1 and ACT2. An upper surface of the first edge portion E1 of the first and second active patterns ACT1 and ACT2 may be exposed to the outside from an inner surface of the bit line trench region BTR.

One lower storage node contact BCx may be separated into a plurality of lower storage node contacts BCx spaced apart from each other in the first direction D1 by the bit line trench regions BTR. One fence pattern FN may be separated into a plurality of fence patterns FN spaced apart from each other in the first direction D1 by the bit line trench regions BTR. During the forming of the bit line trench region BTR, a portion of the upper surface of the word line WL may be recessed. Accordingly, the upper surface of the word line WL may be divided into a first upper surface W1a and a second upper surface W2a.

For example, although not shown in the drawing, when forming the bit line trench regions BTR, a gate capping pattern GC may be formed to protrude further in the seventh direction D7 than the gate dielectric pattern GI. This may be adjusted using the etch selectivity of the gate capping pattern GC with respect to surrounding components (e.g., active patterns ACT1 and ACT2 and gate dielectric pattern GI, etc.). When the bit line trench regions BTR is formed, the gate capping pattern GC may be removed to a smaller extent than the surrounding components, and accordingly, the gate capping pattern GC may protrude more than the surrounding components, and a semiconductor device may be formed to have the characteristics described with reference to FIG. 5.

A bit line spacer BSP may be formed inside the bit line trench region BTR. The bit line spacer BSP may be formed to cover the inner surface of the bit line trench region BTR. As an example, a pair of bit line spacers BSP may cover opposite inner sides of the bit line trench region BTR, respectively. The bit line spacer BSP may not cover at least a portion of the first edge portion E1 of the first and second active patterns ACT1 and ACT2. For example, between a pair of bit line spacers BSP, the upper surface of the first edge portion E1 of the first and second active patterns ACT1 and ACT2 may be exposed to the outside.

A lower bit line BLx may be formed on the exposed upper surface of the first edge portion E1 of the first and second active patterns ACT1 and ACT2. The upper bit line BLy may be formed on a lower bit line BLy. The lower bit line BLx and the upper bit line Bly may constitute a bit line BL. As an example, the lower bit line BLx may be formed through selective epitaxial growth (SEG) using the upper surface of the first edge portion E1 of the first and second active patterns ACT1 and ACT2 as a seed layer. Through the SEG process, the lower bit line BLx may be selectively grown on the upper surface of the first edge portion E1 of the first and second active patterns ACT1 and ACT2. For example, the lower bit line BLx and upper bit line BLy may be formed sequentially. As an example, after forming the bit line BL, a separate process may be performed to distinguish the lower bit line BLx from the upper bit line Bly. Thereafter, bit line capping patterns BCP may be formed on the bit lines BL to fill the remainder of each of the bit line trench regions BTR. A mold pattern MP may be formed to cover the entire surface of the substrate 100.

Referring to FIGS. 1A to 2D, contact holes CH may be formed to penetrate the mold pattern MP. For example, the formation of the contact holes CH may include forming a mask pattern (not shown) including holes (not shown) to cover an upper surface of the mold pattern MP, and performing a removal process on the mold pattern MP using the mask pattern as an etch mask. The contact holes may CH be formed to be arranged in a line in the first direction D1 or in a zigzag shape in the fourth direction D4.

Upper storage node contacts BCy may be formed inside each of the contact holes CH. A second silicide pattern SC may be formed in the contact hole CH and may be disposed on the upper storage node contact BCy. As an example, a second barrier pattern (not shown) may be further formed together with the second silicide pattern SC. Thereafter, landing pads LP may be formed to fill the remainder of each of the contact holes CH. An upper surface of the landing pad LP may be positioned at substantially the same level as the upper surface of the mold pattern MP and may be coplanar. Afterwards, a data storage pattern DSP may be formed on each of the landing pads LP.

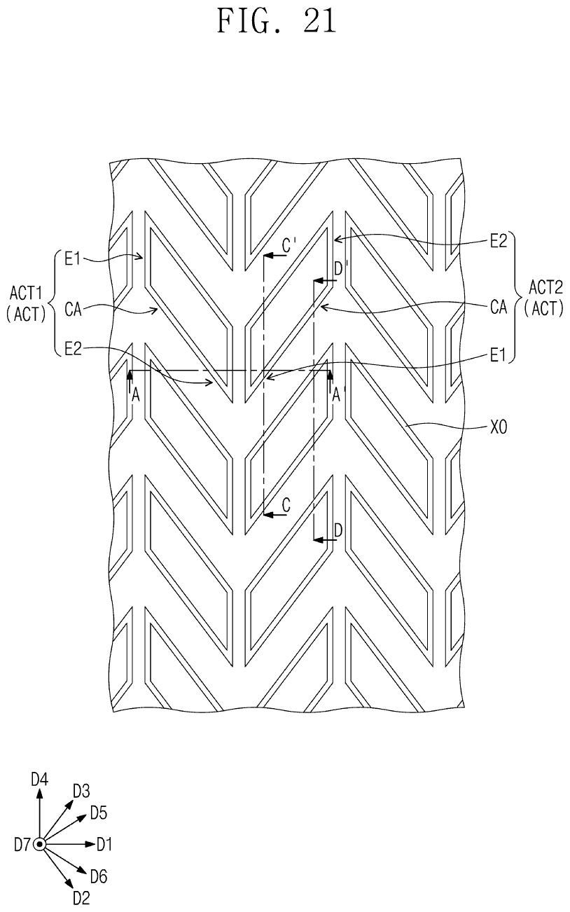

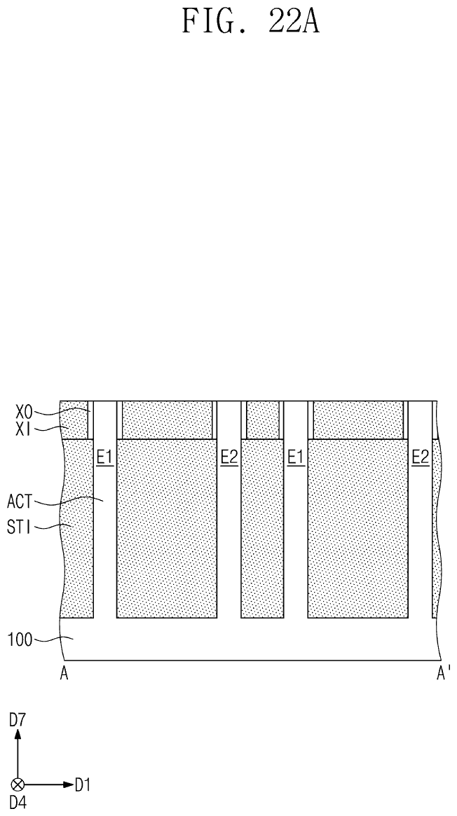

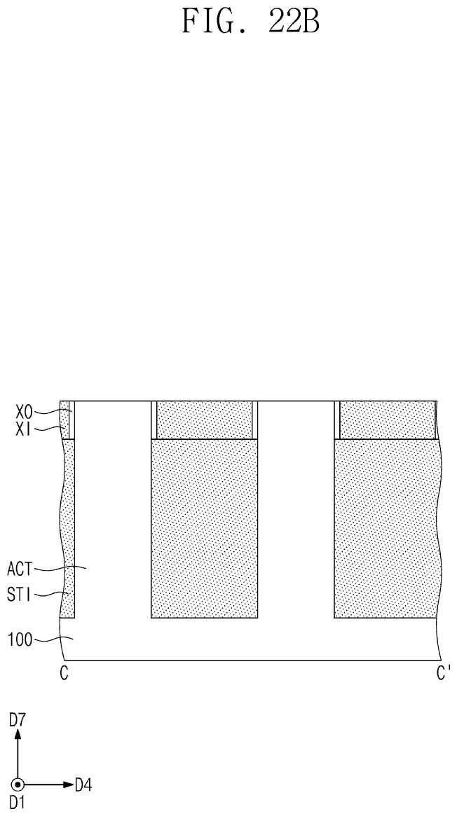

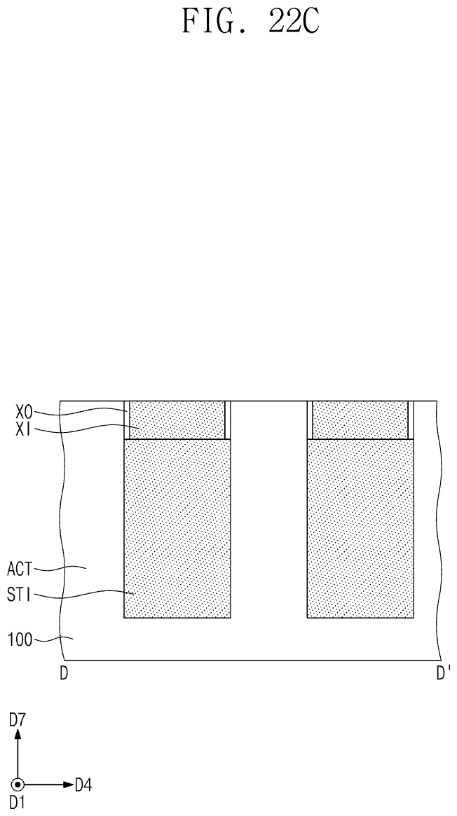

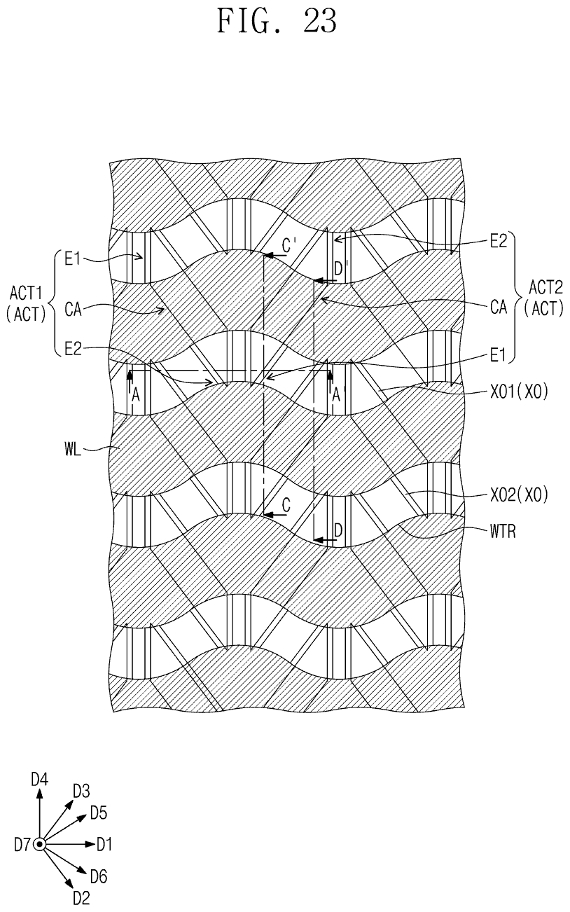

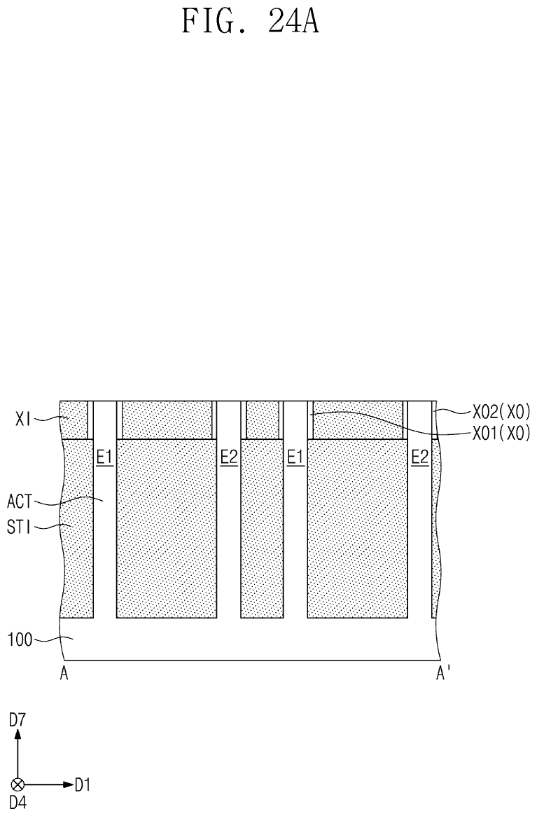

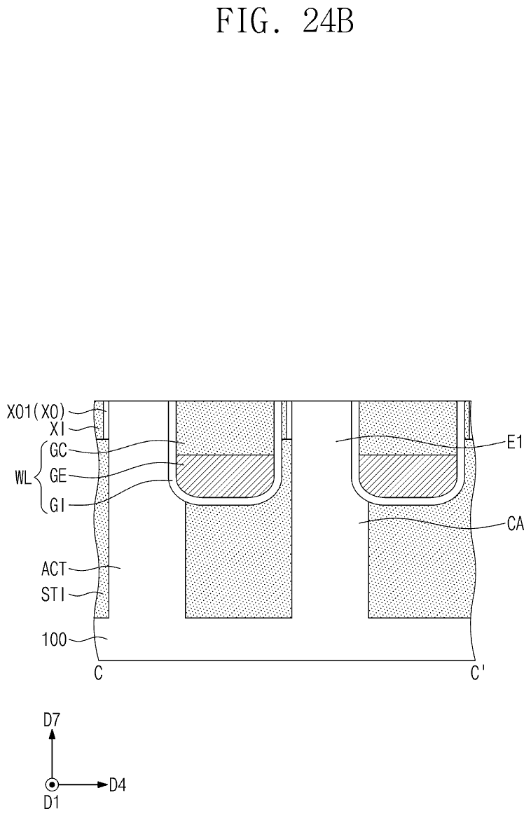

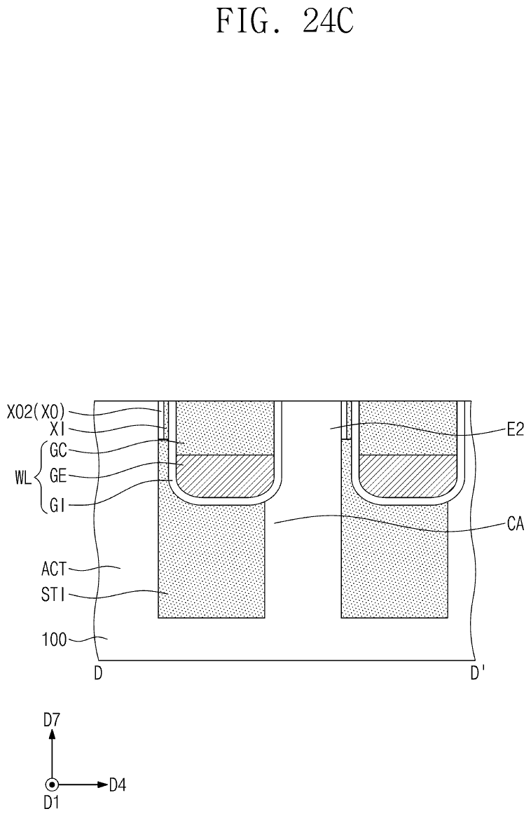

FIGS. 21 to 24C are diagrams showing a method of manufacturing a semiconductor device according to some embodiments of the inventive concept. In detail, FIGS. 21 and 23 are plan views showing a method of manufacturing a semiconductor device according to some embodiments of the inventive concept. FIGS. 22A and 24A are cross-sectional views corresponding to line A-A′ of FIGS. 21 and 23, respectively. FIGS. 22B and 24B are cross-sectional views corresponding to line C-C′ of FIGS. 21 and 23, respectively. FIGS. 22C and 24C are cross-sectional views corresponding to line D-D′ of FIGS. 21 and 23, respectively.

Referring to FIGS. 21 to 22C, after the forming of the device isolation pattern STI described with reference to FIGS. 17 to 18D, a removal process for the device isolation pattern STI may be performed. When the removal process is performed, upper side surfaces of the first and second edge portions E1 and E2 of the first and second active patterns ACT1 and ACT2 may be exposed to the outside.

An active pad XO may be formed to surround the upper side surfaces of the first and second edge portions E1 and E2 of the first and second active patterns ACT1 and ACT2. Thereafter, a pad insulation pattern XI may be formed on the device isolation pattern STI.

Referring to FIGS. 23 to 24C, the word line WL may be formed to cross the first and second active patterns ACT1 and ACT2, the device isolation pattern STI, and the active pad XO. Forming of the word line WL may be the same/similar to that described with reference to FIGS. 17 to 18D. During the forming of the word line WL, the active pad XO may be separated into a first active pad XO1 and a second active pad XO2.

Thereafter, the semiconductor device described with reference to FIGS. 6 to 7C may be formed using the semiconductor device manufacturing method described above.

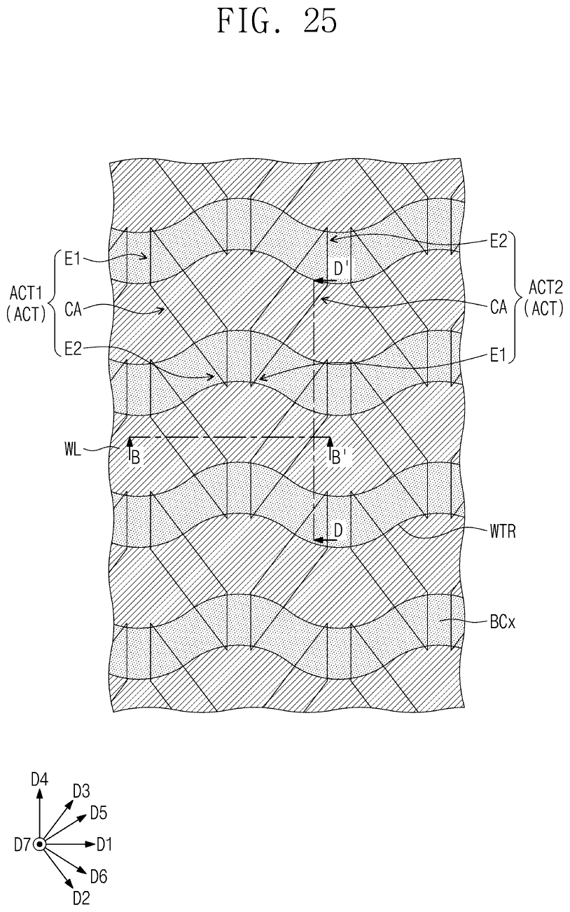

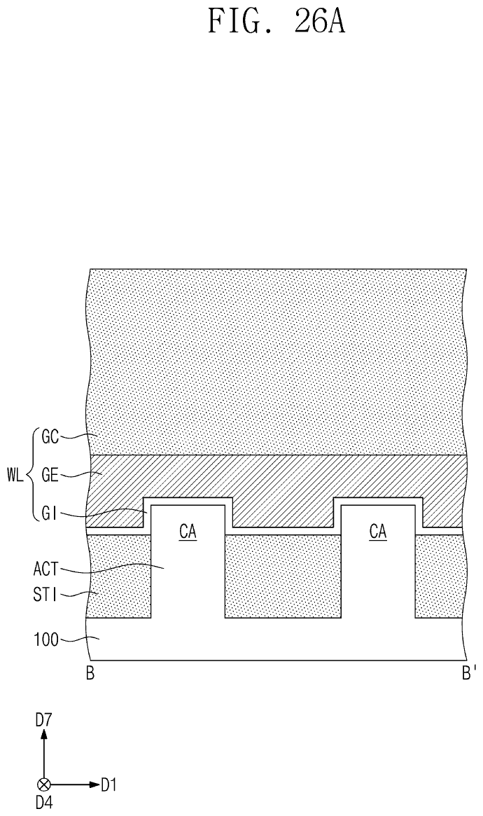

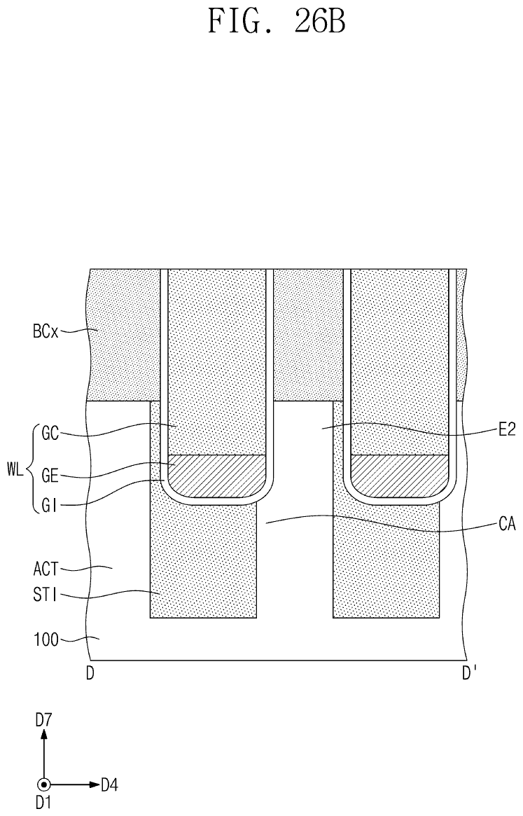

FIGS. 25 to 26B are diagrams showing a method of manufacturing a semiconductor device according to some embodiments of the inventive concept. In detail, FIG. 25 is a plan view showing a method of manufacturing a semiconductor device according to some embodiments of the inventive concept. FIG. 26A is a cross-sectional view corresponding to line B-B′ cross-section of FIG. 25. FIG. 26B is a cross-sectional view corresponding to line D-D′ cross-section of FIG. 25.

Referring to FIGS. 25 to 26B, after the forming of the device isolation pattern STI described with reference to FIGS. 17 to 18D, before forming the word line WL, the lower storage node contact layer (not shown) may be formed on the entire surface of the substrate 100.

Thereafter, the word line WL may be formed to cross the first and second active patterns ACT1 and ACT2 and the device isolation pattern STI. The word line WL may be formed to penetrate the lower storage node contact layer. Accordingly, a plurality of lower storage node contacts BCx may be formed, spaced apart from each other in the fourth direction D4 and each extending in the first direction D1. The forming of the fence pattern FN to space the lower storage node contacts BCx in the fourth direction D4 may be omitted.

Thereafter, the semiconductor device described with reference to FIGS. 8 to 9B may be formed using the semiconductor device manufacturing method described above.

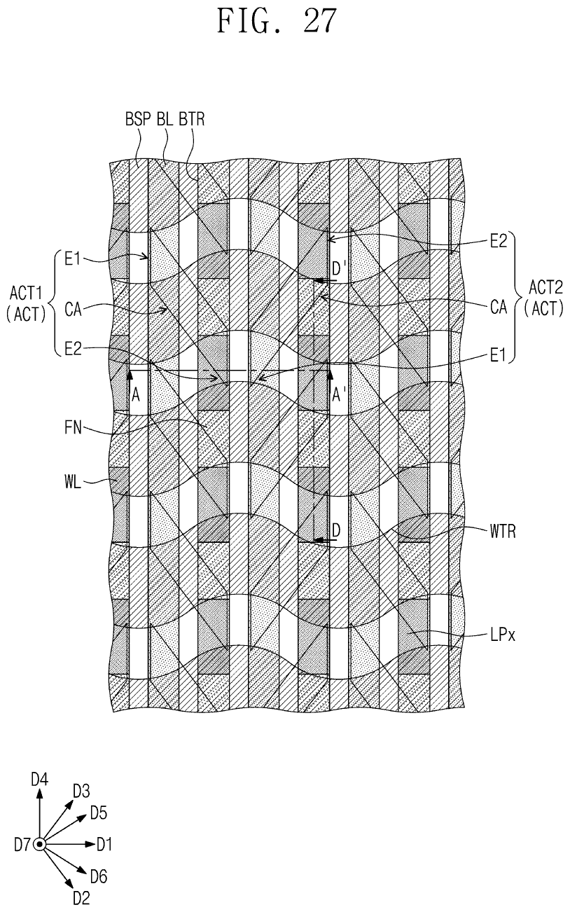

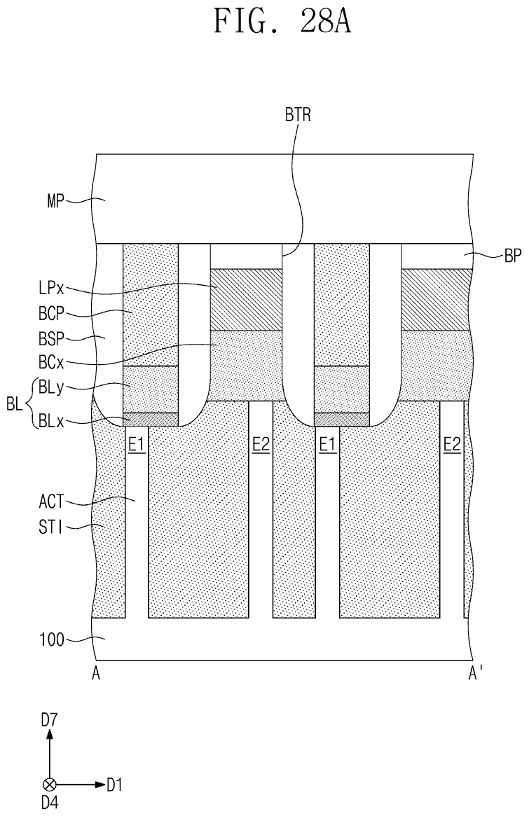

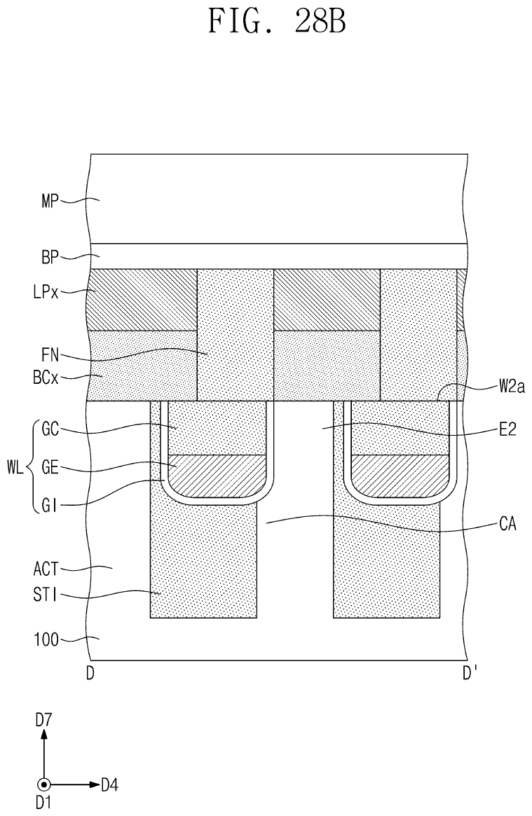

FIGS. 27 to 28B are diagrams showing a method of manufacturing a semiconductor device according to some embodiments of the inventive concept. In detail, FIG. 27 is a plan view showing a method of manufacturing a semiconductor device according to some embodiments of the inventive concept. FIG. 28A is a cross-sectional view corresponding to line A-A′ of FIG. 27. FIG. 28B is a cross-sectional view corresponding to line D-D′ of FIG. 27.

Referring to FIGS. 27 to 28B, after forming the word line WL described with reference to FIGS. 17 to 18D, a lower storage node contact layer (not shown) and a lower landing layer (not shown) may be formed to be sequentially stacked on the substrate 100.

A fence pattern FN may be formed to extend in the first direction D1 and may be disposed on the word line WL. The fence pattern FN may be formed to penetrate a lower storage node contact layer (not shown) and a lower landing layer (not shown). Accordingly, lower storage node contacts BCx spaced apart from each other in the fourth direction D4 and each extending in the first direction D1, and lower landing pads LPx spaced apart from each other in the fourth direction D4 and each extending in the first direction D1 may be formed. Afterwards, a buffer pattern BP may be formed on the upper landing pads LPx.

The bit line trench region BTR, bit line spacer BSP, bit line BL, and bit line capping pattern BCP may be formed in order, and forming the bit line trench region BTR, bit line spacer BSP, bit line BL, and bit line capping pattern BCP may be similar to that described with reference to FIGS. 19 to 20D. When forming the bit line trench region BTR, one lower storage node contact BCx and one lower landing pad LPx may be separated into lower storage node contacts BCx spaced apart from each other in the first direction D1 and lower landing pads LPx spaced apart from each other in the first direction D1. Thereafter, a mold pattern MP may be formed on the entire surface of the substrate 100.

Referring again to FIGS. 10 to 11B, contact holes CH may be formed to penetrate the mold pattern MP. Forming the contact holes CH may be similar to that described with reference to FIGS. 1A to 1C and 2A to 2D.

Thereafter, the process of forming the upper storage node contacts BCy and the second silicide patterns SC described with reference to FIGS. 1A to 1C and 2A to 2D may be omitted.

Each of upper landing pads LPy may be formed to fill the remainder of a corresponding one of the contact holes CH. A data storage pattern DSP may be formed on each of the upper landing pads LPy.

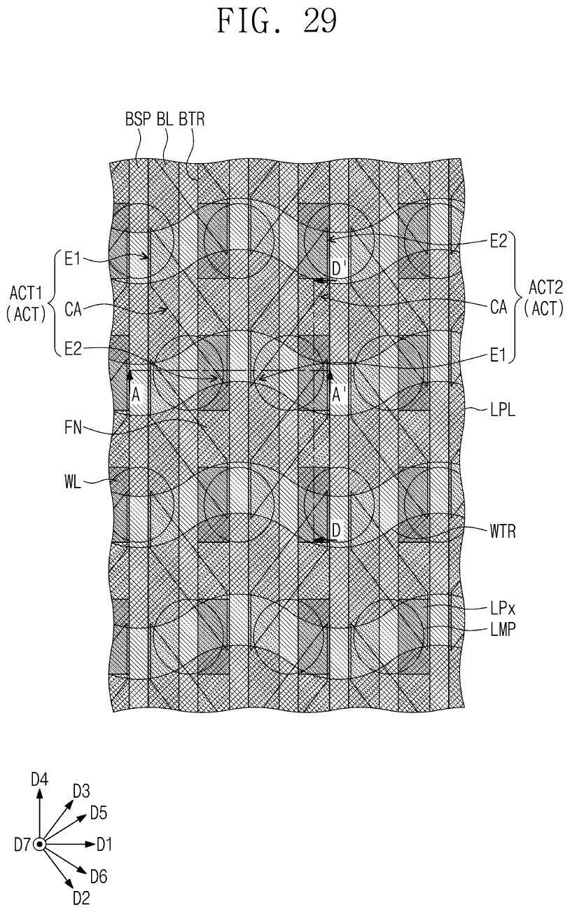

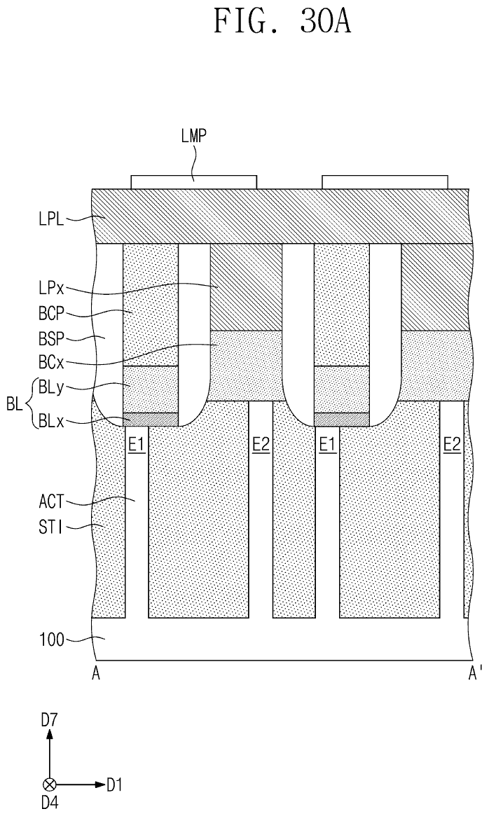

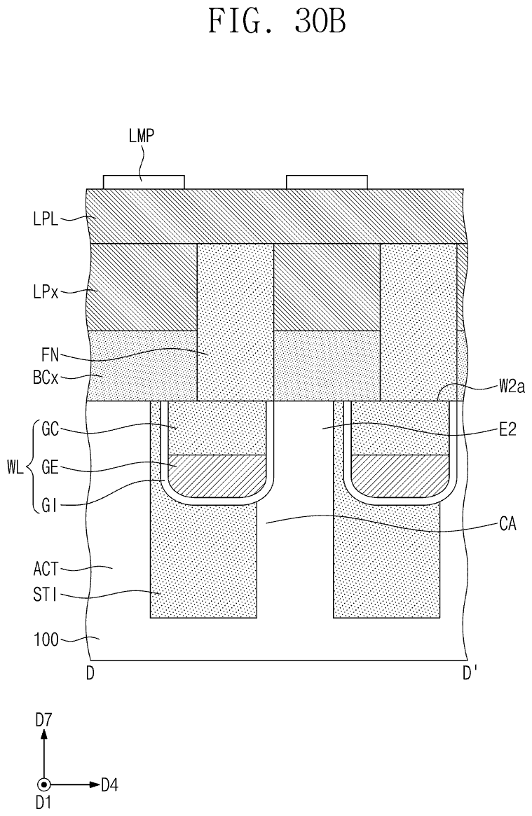

FIGS. 29 to 30B are diagrams showing a method of manufacturing a semiconductor device according to some embodiments of the inventive concept. In detail, FIG. 29 is a plan view showing a method of manufacturing a semiconductor device according to some embodiments of the inventive concept. FIG. 30A is a cross-sectional view corresponding to line A-A′ of FIG. 29. FIG. 30B is a cross-sectional view corresponding to line D-D′ of FIG. 29.

Referring to FIGS. 29 to 30B, after forming the bit line capping pattern BCP described with reference to FIGS. 27 to 28B, an upper landing pad layer LPL may be formed to cover the entire surface of the substrate 100. Forming the buffer pattern BP described with reference to FIGS. 27 to 28B and forming the upper storage node contact BCy and the second silicide pattern SC described with reference to FIGS. 1A to 1C and 2A to 2D may be omitted.

Landing pad mask patterns LMP may be formed on the upper landing pad layer LPL. When viewed in a plan view, positions of the landing pad mask patterns LMP may be similar to the positions of the contact holes CH described with reference to FIGS. 1A to 1C and 2A to 2D. The landing pad mask patterns LMP may be arranged in a line in the first direction D1 and in a zigzag shape in the fourth direction D4.

Referring again to FIGS. 10, 12A, and 12B, the upper landing pad layer LPL may be removed using the landing pad mask patterns LMP as an etch mask to form a plurality of upper landing pads LPy.

Thereafter, a filling pattern FIL may be formed in the region where the upper landing pad LPy was removed. The filling pattern FIL may be formed to surround each of the upper landing pads LPy. A data storage pattern DSP may be formed on each of the upper landing pads LPy.

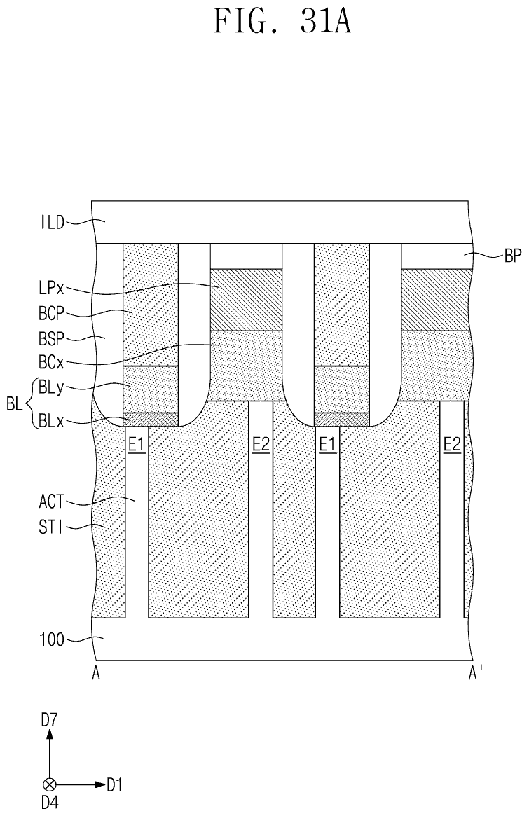

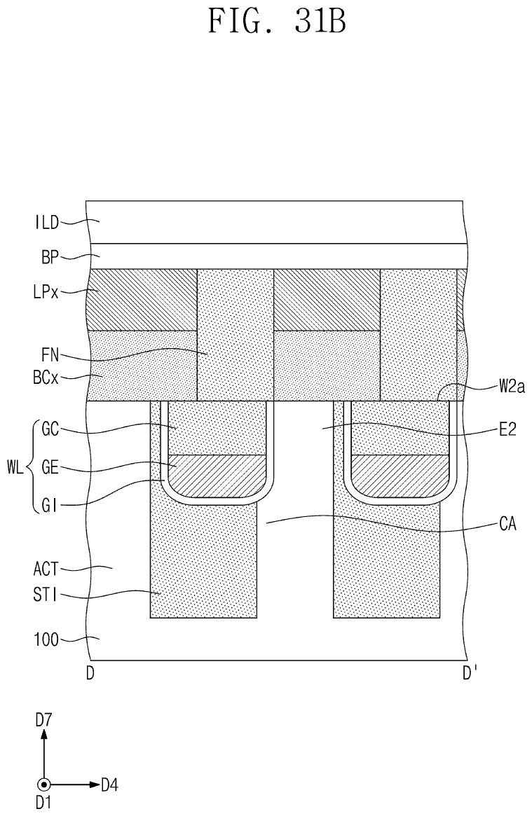

FIGS. 31A and 31B are diagrams showing a method of manufacturing a semiconductor device according to some embodiments of the inventive concept. In detail, FIG. 31A is a cross-sectional view corresponding to line A-A′ of FIG. 27. FIG. 31B is a cross-sectional view corresponding to line D-D′ of FIG. 27.

Referring to FIGS. 31A and 31B, after forming the bit line capping pattern BCP described with reference to FIGS. 27 to 28B, an interlayer insulating layer ILD may be formed on the entire surface of the substrate 100.

Referring again to FIGS. 13 to 14D, the contact holes CH may be formed to penetrate the interlayer insulating layer ILD. Forming the contact holes CH may be similar to that described with reference to FIGS. 1A to 1C and 2A to 2D.

Forming each of the upper storage node contact BCy, second silicide pattern SC, and landing pad LP described with reference to FIGS. 1A to 1C and 2A to 2D may be omitted.

Lower electrodes BE may be formed on the contact holes CH. Forming the lower electrodes BE may include forming a lower electrode layer (not shown) that fills the contact holes CH and covers an upper surface of the interlayer insulating layer ILD, and removing a portion of the lower electrode layer to form the lower electrodes BE. The lower electrode BE may include a lower portion BEx and an upper portion BEy.

A dielectric layer DL may be formed to conformally cover an upper surface of the interlayer insulating layer ILD and the upper portions BEy of the lower electrodes BE. Thereafter, an upper electrode TE may be formed between the upper portions BEy of the lower electrodes BE and on the upper portions BEy of the lower electrodes BE.

According to some embodiments, the first and second active patterns may be arranged side by side in the first direction (or the opposite direction) or the fourth direction (or the opposite direction), thereby simplifying the arrangement of components in the semiconductor device. Accordingly, the difficulty of patterning for forming the semiconductor device may be reduced, thereby facilitating the manufacturing of the semiconductor device. Additionally, such an arrangement of the first and second active patterns may be desirable for the integration of the semiconductor device.

According to some embodiments, the word line may extend in the wave shape in the first direction between the first and second edge portions of each of the first and second active patterns. Accordingly, the contact area between the first edge portion of the first active pattern and the bit line contact and the contact area between the second edge portion of the first active pattern and the lower storage node contact may increase. In addition, the contact area between the first edge portion of the second active pattern and the bit line and the contact area between the second edge portion of the second active pattern and the lower storage node contact may increase. As a result, the electrical resistance between each contacting components may be reduced, and the electrical characteristics of the semiconductor device may be improved.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor device comprising:
a substrate provided with a first active pattern and a second active pattern, wherein the first active pattern and the second active pattern are adjacent to each other in a first direction, each of the first active pattern and the second active pattern includes a first edge portion, a second edge portion, a center portion therebetween, and the first direction is parallel to an upper surface of the substrate;
a word line having a wave shape extending in the first direction and including a first portion overlapping the center portion of the first active pattern and a second portion overlapping the center portion of the second active pattern;
a first bit line disposed on the first edge portion of the first active pattern; and
a first storage node contact disposed on the second edge portion of the first active pattern,
wherein the first active pattern extends lengthwise in a second direction intersecting the first direction, and the second direction is parallel to the upper surface of the substrate,
wherein the second active pattern extends lengthwise in a third direction intersecting the first direction and the second direction, and the third direction is parallel to the upper surface of the substrate, and
wherein the first active pattern and the second active pattern are symmetric in shape.

2. The semiconductor device of claim 1,
wherein the first edge portion, the first portion of the word line, and the second edge portion of the first active pattern are sequentially disposed in the second direction.

3. The semiconductor device of claim 2, further comprising:
a second bit line disposed on the first edge portion of the second active pattern,
wherein the first edge portion of the first active pattern and the second edge portion of the second active pattern is spaced apart from each other at a first distance in the first direction.

4. The semiconductor device of claim 3, further comprising: a second storage node disposed on the second edge portion of the second active pattern,
wherein the second edge portion of the second active pattern is spaced apart from the first edge portion of the first active pattern at a second distance in the first direction, and
wherein the second distance is different from the first distance.

5. The semiconductor device of claim 2,
wherein the second edge portion, the second portion of the word line, and the first edge portion of the second active pattern are sequentially disposed in the third direction.

6. The semiconductor device of claim 1,
wherein the first active pattern and the second active pattern, when viewed in a plan view, are spaced increasingly farther apart in the first direction along an imaginary line between therebetween, and
wherein the imaginary line extends in a fourth direction parallel to the upper surface of the substrate and perpendicular to the first direction.

7. The semiconductor device of claim 1,
wherein the first active pattern is repeatedly positioned in the first direction to form a plurality of first active patterns,
wherein the second active pattern is repeatedly positioned in the first direction to form a plurality of second active patterns, and
wherein each of the plurality of first active patterns and each of the plurality of second active patterns are alternately arranged in the first direction.

8. The semiconductor device of claim 1,
wherein the word line has a first side on the first edge portion of the first active pattern and a second side opposing the first side, and
wherein, when viewed in a plan view, each of the first side and the second side of the word line has a concave surface.

9. The semiconductor device of claim 8,
wherein, when viewed in a plan view, the concave surface of the first side of the word line and the concave surface of the second side of the word line are concave toward opposite directions.

10. The semiconductor device of claim 8,
wherein, when viewed in a plan view, the first edge portion of the first active pattern and the second edge portion of the second active pattern are provided on the concave surface of the first side of the word line.

11. The semiconductor device of claim 8,
wherein, when viewed in a plan view, the second edge portion of the first active pattern and the first edge portion of the second active pattern are provided on the concave surface of the second side of the word line.

12. The semiconductor device of claim 1,
wherein the wave shape of the word line has a substantially constant width in a fourth direction parallel to the upper surface of the substrate and perpendicular to the first direction.

13. A semiconductor device comprising:
a first active pattern and a second active pattern adjacent to each other in a first direction, each of the first and second active patterns including a first edge portion and a second edge portion spaced apart from each other;
a word line crossing between the first and second edge portions of each of the first and second active patterns and extending in the first direction;
a bit line on the first edge portion of the first active pattern; and
a storage node contact on the second edge portion of the first active pattern,
wherein the first active pattern extends lengthwise in a second direction intersecting the first direction,
wherein the second active pattern extends lengthwise in a third direction intersecting the first direction and the third direction,
wherein the second direction and the third direction are symmetrical with respect to the first direction,
wherein the first direction, the second direction, and the third direction are on the same plane, and
wherein each of opposite sides of the word line has convex surfaces and concave surfaces alternately arranged in the first direction.

14. The semiconductor device of claim 13,
wherein, when viewed in a plan view, each of the opposite sides of the word line has a wave shape extending in the first direction.

15. The semiconductor device of claim 13,
wherein, when viewed in a plan view, the concave surfaces on one side of the opposite sides of the word line and the concave surfaces on the other side are concave toward opposite directions.

16. The semiconductor device of claim 13,
wherein the convex surfaces on one side of the opposite sides of the word line and the convex surfaces on the other side are convex toward opposite directions.

17. The semiconductor device of claim 13,
wherein the convex surfaces of one of the opposite sides of the word line are adjacent to the concave surfaces of the other side of the opposite sides of the word line in the second direction or the third direction.

18. The semiconductor device of claim 13,
wherein the first active pattern is repeatedly positioned in the first direction to form a plurality of first active patterns,
wherein the second active pattern is repeatedly positioned in the first direction to form a plurality of second active patterns, and
wherein each of the plurality of first active patterns and each of the plurality of second active patterns are alternately arranged in the first direction.

19. A semiconductor device comprising:
a first active pattern and a second active pattern adjacent to each other in a first direction, each of the first active pattern and the second active pattern including a first edge portion and a second edge portion spaced apart from each other;
a word line crossing between the first and second edge portions of each of the first and second active patterns and having a wave shape extending in the first direction;
a bit line disposed on the first edge portion of the first active pattern;
a storage node contact disposed on the second edge portion of the first active pattern;
a landing pad disposed on the storage node contact; and
a data storage pattern disposed on the landing pad,
wherein the first active pattern extends lengthwise in a second direction intersecting the first direction,
wherein the second active pattern extends lengthwise in a third direction intersecting the first direction and the second direction,
wherein the second direction and the third direction are symmetrical with respect to the first direction, and
wherein the first direction, the second direction, and the third direction are on the same plane.

20. The semiconductor device of claim 19,
wherein each of opposite sides of the word line has convex surfaces and concave surfaces alternately arranged in the first direction.
